(19) United States
(12) Patent Application Publication
(10) Pub. No.: US 2015/0087110 A1
(43) Pub. Date: Mar. 26, 2015

(54) Low-Temperature Fabrication of Spray-Coated Metal Oxide Thin Film Transistors

(71) Applicants: Northwestern University, Evanston, IL (US); Polyera Corporation, Skokie, IL (US)

(72) Inventors: Antonio Facchetti, Chicago, IL (US); Tobin J. Marks, Evanston, IL (US); Xinge Yu, Chicago, IL (US); Yu Xia, Northbrook, IL (US); William Christopher Sheets, Chicago, IL (US)

(21) Appl. No.: 14/493,280

(22) Filed: Sep. 22, 2014

Related U.S. Application Data
(60) Provisional application No. 61/880,892, filed on Sep. 21, 2013.

(51) Int. Cl. H01L 29/66; H01L 29/786; H01L 21/02

(52) U.S. Cl. CPC H01L 29/66969; H01L 21/02565; H01L 21/02614; H01L 21/02628; H01L 29/78684
USPC 438/104

(57) ABSTRACT

The present teachings relate to a method of enabling metal oxide film growth via solution processes at low temperatures (≦350° C.) and in a time-efficient manner. The present thin films are useful as thin film semiconductors, thin film dielectrics, or thin film conductors, and can be implemented into semiconductor devices such as thin film transistors and thin film photovoltaic devices.

### CROSS-REFERENCE TO RELATED APPLICATIONS

This application claims priority to and the benefit of U.S. Provisional Patent Application Ser. No. 61/880,892, filed on Sep. 21, 2013, the disclosure of which is incorporated by reference herein in its entirety.

### STATEMENT REGARDING FEDERALLY SPONSORED RESEARCH OR DEVELOPMENT

This invention was made with government support under grant number N00014-11-1-0690 awarded by the Office of Naval Research and grant number DMR-1121262 awarded by the National Science Foundation. The government has certain rights in the invention.

### BACKGROUND

Solution-processed metal-oxide (MO) semiconductors have emerged as an appealing materials for next-generation electronic devices owing to their various advantages including low cost, high carrier mobilities, good environmental/thermal stability, and excellent optical transparency. Recent active research has inspired their applications in various large-area electronics, such as rigid and flexible displays, integrated logic circuits, flexible circuitry, sensor arrays, and radio frequency identification (RFID) tags. In fabricating high-performance electronics with acceptable fidelity, conventional fabrication processes typically involve highly capital-intensive physical and chemical vapor deposition techniques. However, these methodologies are not easily compatible with high-throughput, large-area roll-to-roll (R2R) electronic device production. Taking full advantage of the solubility of MO precursors in common organic solvents, several conventional solution-based methods have been utilized to fabricate MO semiconducting active layers for thin-film transistors (TFTs). However, the field-effect mobilities of these solution-processed MO TFTs are not yet competitive with the corresponding vapor-processed (e.g., sputtered) devices. Therefore, developing solution fabrication technologies for MO TFTs having performance parameters comparable to state-of-the-art vapor-deposited devices is viewed as the next milestone for MO-based electronics.

For example, sol-gel processing techniques have been extensively used to fabricate high-quality metal oxide films, which have enabled the rapid development of coatings and films, including those for high-performance TFTs. However, the necessary condensation, densification, and impurity removal steps applied to sol-gel precursor films typically require high annealing temperatures (>400-500° C.) to provide good electronic performance, which are incompatible with inexpensive glasses and typical flexible plastic substrates. Progress toward greatly reducing the processing temperatures of sol-gel derived MO films has afforded improved TFT mobilities; however, achieving both reproducible high performance and stable device operation remain an unresolved issue for Ga-containing materials.

Recently, a novel solution-phase method making use of “combustion” precursors has been reported to fabricate MO TFTs at significantly lower temperatures than typical sol-gel processing techniques. Specifically, by pre-mixing an oxidizer (e.g., a metal nitrate salt) and a fuel (e.g., acetylacetone) in a precursor solution, a highly exothermic and localized chemical transformation occurs within the spin-coated films during post-annealing treatment, which results in rapid and efficient condensation and M-O-M lattice formation at low temperatures (150-300° C.). With this approach, new semiconducting metal oxide compositions have been explored and high-performance MO-based TFTs enabled, including flexible indium oxide (In₂O₃) devices with mobilities ˜6 cm²V⁻¹s⁻¹, fabricated on polymer substrates at temperatures as low as 200° C.

However, considerable quantities of gaseous by-products, primarily H₂O and CO₂, and optionally N₂ and NO_{R}, are evolved during the post annealing step. These gaseous by-products can severely disrupt film continuity and create highly porous films if thick film growth is attempted in a single coating step. These concerns are especially critical for combustion synthesis because the exotherm has a short duration. Therefore, to form dense, high-quality oxide films using the spin-coating combustion method, film thicknesses need to be controlled to <5-10 nm per layer. Meanwhile, for MO TFT applications in circuits and active-matrix display backplanes, the oxide semiconductor layer needs to be approximately 50-100 nm thick to avoid back-channel effects, delayed turn-on, and bias stress shifting. This means that for current-generation solution-phase processed MO semiconductors and TFT structures, multiple time-consuming deposition and post annealing cycles are required to fabricate oxide films of sufficient thickness. Such approaches are inefficient and can risk creating bulk trap states at the interfaces of the semiconducting layers.

Accordingly, there is a need in the art for a new solution-phase process that can be used to fabricate high-performance electronic metal oxide thin films more efficiently at low temperatures.

### SUMMARY

In light of the foregoing, the present teachings provide a new process that can be used to achieve the solution deposition of diverse electronic metal oxide films at low temperatures and in a time-efficient manner, while affording metal oxide films with better electronic properties compared to other conventional solution-phase methods. In particular, the present method can enable scalable fabrication of technologically relevant metal oxide films and film requisite thicknesses in a single deposition step and within minutes. By reducing trapping of gaseous by-products during film growth, high-quality, nanoscopically dense, macroscopically continuous films can be produced for both crystalline and amorphous metal oxide semiconductors and conductors, yielding high-performance semiconductor devices such as thin film transistors for the former and high thin-film conductivities for the latter.

Generally, the present process includes contacting a substrate with an aerosol of a precursor composition while the substrate is annealed in situ at a temperature ranging between about 100° C. and about 350° C. The precursor composition includes a redox pair of precursors (a fuel and an oxidizing agent) that are chosen to induce an exothermic reaction as the precursors are converted into metal oxides, thus, a relatively low annealing temperature is sufficient to initiate the conversion. In addition, by heating the substrate while the precursor composition is deposited onto it as an aerosol, post-deposition annealing is rendered unnecessary. Accordingly, the present process can be used to prepare electrically functional metal oxide films at annealing temperatures generally below about 350° C., while limiting fabrication times to a fraction of an hour compared to multiple hours as required by spin-coating methods, including spin-coating methods using combustion precursors.

The present teachings also relate to the implementation of the resulting films in various semiconductor devices. For example, the present low temperature-processed metal oxide thin films can be incorporated into articles of manufacture such as field effect transistors (e.g., thin film transistors), photovoltaics, organic light emitting devices such as organic light emitting diodes (OLEDs) and organic light emitting transistors (OLETs), complementary metal oxide semiconductors (CMOSs), complementary inverters, D flip-flops, rectifiers, ring oscillators, solar cells, photovoltaic devices, photodetectors, and sensors. The present low temperature solution-processed metal oxide thin films can be combined with metal oxide (e.g., IGZO), nitride (e.g., Si₃N₄), arsenite (e.g., GaAs), or organic semiconductor (e.g., rylenes, donor-acceptor blends) films deposited via other solution-phase processes or conventional methods such as thermal evaporation and various physical and chemical vapor deposition techniques (e.g., sputtering, plasma-enhanced chemical vapor deposition (PECVD), atomic layer deposition (ALD), pulsed laser deposition (PLD), and ion-assisted deposition (IAD)) to produce hybrid multilayers. In particular, high-performance transistors on inexpensive and/or flexible substrates can be achieved by implementing the present metal oxide films as the electrically transporting (e.g., the semiconductor and/or any of the source, drain, and gate electrode(s)) and/or the electrically insulating (e.g., the gate dielectric) component(s). The present low temperature-processed metal oxide thin films can provide advantageous field-effect mobilities, which, without wishing to be bound by any particular theory, can be achieved through improved film texturing and/or interfacial and related morphological considerations.

The foregoing as well as other features and advantages of the present teachings will be more fully understood from the following figures, description, examples, and claims.

### BRIEF DESCRIPTION OF DRAWINGS

It should be understood that the drawings described below are for illustration purposes only. The drawings are not necessarily to scale, with emphasis generally being placed upon illustrating the principles of the present teachings. The drawings are not intended to limit the scope of the present teachings in any way.

FIG. 1 compares the energetics of combustion synthesis versus conventional sol-gel synthesis of metal oxides. To illustrate, a metal nitrate is used as the oxidizing agent while acetylacetone is used as the fuel.

FIG. 2 compares the processing steps of (a) the prior art spin-coating combustion synthesis (Spin-CS) versus (b) the present method (spray-coating combustion synthesis, SCCS) as implemented in the fabrication of a bottom gate metal oxide thin film transistor (MO TFT).

FIGS. 3a and 3b shows x-ray diffraction (XRD) pattern of In₂O₃ films at different annealing temperatures deposited using (a) the Spin-CS method, and (b) the SCCS method. FIGS. 3c and 3d shows x-ray photoelectron spectroscopy (XPS) spectra of In₂O₃ films deposited using (c) the Spin-CS method, and (d) the SCCS method (529.9±0.1 eV: M-O-M lattice oxygen; 531.3±0.1 eV: M-OH metal hydroxide oxygen; 532.2±0.1 eV: adsorbed oxygen species).

FIGS. 4a and 4b show (a) HAADF STEM images, and (b) high resolution bright field TEM images and selected area energy-filtered electron diffraction patterns of In₂O₃ films deposited using the Spin-CS method, and deposited using the SCCS method on SiO₂ annealed at 300° C.

FIGS. 5a-c show typical transfer and output characteristics of metal oxide TFTs fabricated on 300 nm SiO₂/Si by the Spin-CS (or “Spin”) method and the SCCS (or (“Spray”) method: (a) In₂O₃ devices annealing at 200° C., (b) IZO devices annealing at 250° C., and (c) IGZO devices annealing at 300° C.

FIG. 6 compares the transistor transfer characteristics and mobility distribution statistics for 20 nm thick metal oxide TFTs fabricated on SiO₂/Si substrates (unless indicated otherwise) by spin-coating combustion (Spin-CS, 4 MO layers each 5 nm thick) and SCCS (single 20 nm MO layer): (a) saturation mobility distribution for In₂O₃ annealed at the indicated temperatures, (b) saturation mobility distribution for IZO (In:Zn=1:0.43) annealed at the indicated temperatures, with the last panel referring to statistics for ZrOx/ITO substrates, and (c) saturation mobility distribution for IGZO (In:Ga:Zn=1:0.11:0.29) annealed at the indicated temperatures, with the last panel referring to statistics for ZrOx/ITO substrates.

FIG. 7 characterizes the performance of a representative Arylite™/Al(gate)/Al₂O₃/In₂O₃/Al(source/drain) TFT fabricated by SCCS and annealed at 200° C.: (a) C-V measurements at 10 kHz, and frequency measurements at 2V for the 40 nm Al₂O₃ dielectric layer processed at 200° C., (b) transfer and output characteristics of the flexible SCCS In₂O₃ TFT processed at 200° C., and (c) an optical image of the flexible SCCS In₂O₃ TFT.

FIG. 8 compares the transfer characteristics (V_{D}=80V), bias stress data, and mobility distribution statistics for 50 nm thick single layer IGZO TFTs fabricated by the indicated deposition methods: (a) IGZO composition (1:0.11:0.29) on Si/SiO₂ substrates [last panel: SCCS IGZO/ZrOₓ] annealed at 300° C., (b) corresponding mobility statistics (for sputter, 1:1:1 composition).

FIG. 9 compares the transfer characteristics (V_{D}=80V), bias stress data, and mobility distribution statistics for 50 nm thick single layer IGZO TFTs fabricated by the indicated deposition methods: (a) IGZO composition (1:1:1) on Si/SiO₂ substrates annealed at 350° C., (b) corresponding mobility statistics.

### DETAILED DESCRIPTION

Throughout the application, where compositions are described as having, including, or comprising specific components, or where processes are described as having, including, or comprising specific process steps, it is contemplated that compositions of the present teachings also consist essentially of, or consist of, the recited components, and that the processes of the present teachings also consist essentially of, or consist of, the recited process steps.

In the application, where an element or component is said to be included in and/or selected from a list of recited elements or components, it should be understood that the element or component can be any one of the recited elements or components, or can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein.

The use of the terms “include,” “includes”, “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10% variation from the nominal value unless otherwise indicated or inferred.

It should be understood that the order of steps or order for performing certain actions is immaterial so long as the present teachings remain operable. Moreover, two or more steps or actions may be conducted simultaneously.

The present teachings provide a method for preparing metal oxide thin films where the method itself can confer advantages such as low annealing temperatures, precise thickness control, and short fabrication times, while providing metal oxide thin films with advantages including improved surface morphologies and enhanced electronic properties. In particular embodiments, the present method can be used to fabricate a thin film transistor which includes a thin film semiconductor component composed of a metal oxide thin film prepared according to the present method.

Accordingly, in one aspect, the present teachings can be directed to a method of preparing a metal oxide thin film for use as a thin film semiconductor component in a semiconductor device. The method generally includes contacting a substrate with an aerosol of a precursor composition while the substrate is annealed in situ at a temperature ranging between about 100° C. and about 350° C.

While various precursors have been used in existing solution-phase methods for processing metal oxide thin films, conventional precursors (e.g., a sol-gel system including a metal source, a base catalyst, a stabilizer, and a solvent as described above) typically require high temperatures (≧400° C.) to complete the condensation of the precursor sol, the removal of the organic stabilizer within the thin film, and finally, full densification of the metal oxide thin films. Such high-temperature requirements by any of these steps can risk complications such as film cracking induced by thermal expansion coefficient mismatch. Further, such high processing temperature requirements make these methods incompatible with most conventional flexible plastic substrates. Even in limited cases where the processing temperatures can be lowered, the reported mobilities achieved by the resulting metal oxide thin film semiconductor are limited (˜1 cm²/Vs).

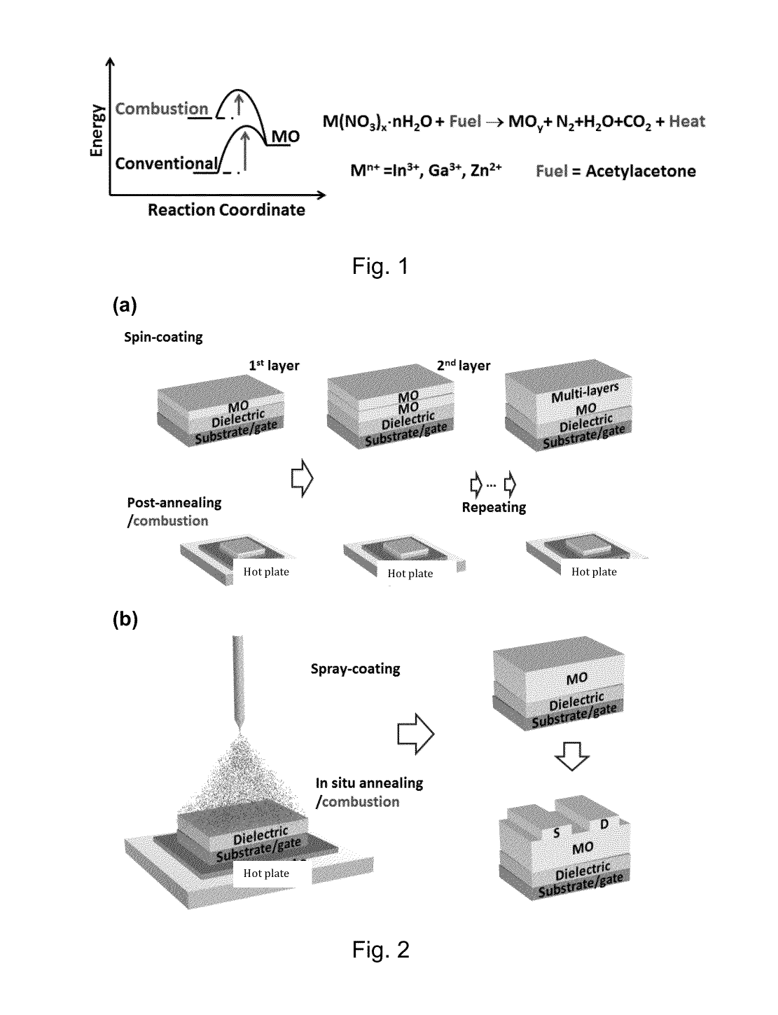

By comparison, the precursor compositions according to the present teachings include a redox pair of precursors (a fuel and an oxidizing agent) that are chosen and provided under conditions to induce a combustion reaction. Specifically, the precursors are selected and provided at amounts such that the fuel and the oxidizing agent react in a series of reactions, over the course of which heat is generated, and the fuel is oxidized by the oxidizing agent and mostly converted into gases including CO₂, H₂O, and optionally N₂. The self-generated heat from the precursors' reaction provides a localized energy supply, thereby eliminating the need for high, externally applied processing temperatures (FIG. 1). Thus, the temperature requirement of the in situ annealing step can be less than about 400° C., preferably about 350° C. or less, about 300° C. or less, about 250° C. or less, about 200° C. or less, about 150° C. or less, or as low as about 100° C.

Also, conventional methods e.g., spin-coating, often require multiple cycles of deposition and post annealing steps to avoid gas buildup and undesirable microstructural features in the oxide thin films if a certain thickness is desired (e.g., >10 nm), which translates into long fabrication times typically in the order of multiple hours (FIG. 2a).

Instead, by adopting a spray-coating approach, a film thickness greater than about 40 nm can be achieved in a fraction of an hour without sacrificing film quality (FIG. 2b). Specifically, because film growth and annealing take place simultaneously, gas accumulation in the film is more suppressed, and the resulting film has smoother surfaces and smaller pore size when compared to spin-coated films of the same thickness, which leads to better electronic properties. As demonstrated by the examples hereinbelow, the present spray-coating combustion synthesis (SCCS) method can yield dense, high-quality macroscopically continuous films of both crystalline and amorphous metal oxide films. Specifically, using a processing temperature as low as 200-225° C., single-layer (20 nm thick) SCCS-processed (In₂O₃, IZO, IGZO) TFTs were found to exhibit carrier mobilities that are at least 2-3 times greater than those achieved by the prior art spin-coating combustion synthesis (Spin-CS) method which also requires much longer processing time due to the need for multiple deposition/annealing cycles to achieve the same film thickness (4×5 nm). When comparing 50 nm IGZO TFTs, SCCS-processed devices were found to exhibit carrier mobilites (as high as ˜20 cm²/Vs) that are 10²-10⁴ times greater than those achieved with conventional sol-gel precursors or the spin-coating combustion synthesis method. In fact, SCCS-processed IGZO films and TFTs were found to have film properties and device performance (including reproducibility and bias-stress stability) that are comparable to magnetron-sputtered IGZO films and TFTs, but without the capital-intensive equipment and high processing temperatures.

Accordingly, in one aspect, the present teachings relate to low-temperature, time-efficient solution-phase methods that can be used to prepare various metal oxide thin films including various thin film metal oxide semiconductors, thin film metal oxide conductors, and thin film metal oxide dielectrics. Exemplary semiconducting metal oxides include indium oxide (In₂O₃), indium zinc oxide (IZO), zinc tin oxide (ZTO), indium gallium oxide (IGO), indium-gallium-zinc oxide (IGZO), tin oxide (SnO₂), nickel oxide (NiO), copper oxide (Cu₂O), and zinc oxide (ZnO). These semiconducting films can have dopants (such as fluorine, sulfur, lithium, rhodium, silver, cadmium, scandium, sodium, calcium, magnesium, barium, and lanthanum) to improve electron (for n-type) or hole (for p-type) mobility and/or conductivity. Exemplary insulating metal oxides include alumina (Al₂O₃), cerium oxide (CeOₓ), yttrium oxide (Y₂O₃), titanium oxide (TiO₂), zirconium oxide (ZrO₂), hafnium oxide (HfO₂), tantalum oxide (Ta₂O₅), and barium and strontium titanium oxide ((Ba,Sr)TiO₃). Exemplary conducting metal oxides include transparent conducting oxides such as indium tin oxide (ITO, or tin-doped indium oxide Sn—In—O where the Sn content is about 10% or less), indium-doped zinc oxide (IZO), zinc indium tin oxide (ZITO), gallium-doped zinc oxide (GZO), gallium-doped indium oxide (GIO), fluorine-doped tin oxide (FTO), gallium indium tin oxide (GITO), and aluminum-doped zinc oxide (AZO).

A precursor composition useful for the present teachings generally includes a fuel and one or more oxidizing agents in a solvent or solvent mixture, wherein the fuel and/or at least one of the oxidizing agent(s) comprise a metal reagent, and wherein the fuel and the one or more oxidizing agents are provided under conditions that would favor combustion reactions. Generally, the fuel and the one or more oxidizing agents are present in substantially stoichiometric amounts to allow formation of the desired metal oxide and complete combustion of the remaining reagents (that is, the stoichiometric ratio should be calculated based on the ideal oxidation of all components). Despite the fact that some variations from the stoichiometric amounts are acceptable, when the precursor composition includes either too much oxidant (e.g., more than ten times exceeding the stoichiometric amount) or too much fuel (e.g., more than ten times exceeding the stoichiometric amount), combustion reactions can be disfavored and such precursor compositions may not allow metal oxide thin films to be formed under the favorable thermodynamics according to combustion chemistry, which may lead to a high level of impurities, poor film morphology, and/or poor electrical connections within the metal-O-metal lattice. In addition, while conventional metal oxide precursor compositions typically include at least one metal alkoxide, the precursor composition used in the present method does not include any alkoxide as a metal source.

Unlike conventional precursors based on sol-gel approaches, which convert the precursor into metal oxides via an endothermic reaction, the oxidizing agent and the fuel in the precursor composition described herein react to induce a self-energy generating combustion. The self-generated heat from the precursors' reaction provides a localized energy supply, thereby eliminating the need for high, externally applied processing temperatures to drive the completion of the metal oxide lattice. Therefore, the present precursor compositions allow metal oxide formation at temperatures much lower than through the use of conventional sol-gel precursors.

Different embodiments of the redox pair of precursors according to the present teachings are possible. In certain embodiments, the present precursor composition can include one or more metal reagents, an organic fuel, and optionally an inorganic reagent, wherein the organic fuel forms a redox pair with at least one of the metal reagents or the inorganic reagent; that is, at least one of the metal reagents or the inorganic reagent comprises an oxidizing anion which can react with the organic fuel (an organic compound) in a combustion reaction to produce CO₂, H₂O, and optionally N₂ and/or other gases depending on the composition of the fuel. In other embodiments, the present precursor composition can include a fuel and an oxidizing agent, wherein the fuel can be in the form of a first metal reagent (i.e., the fuel can take the form of an anion) and the oxidizing agent can be in the form of a second metal reagent (i.e., the second metal reagent can include an oxidizing anion). In yet other embodiments, the fuel can be in the form of a first metal reagent (i.e., the fuel can take the form of an anion), and the oxidizing agent can be an acid or an inorganic reagent comprising an oxidizing anion. In various embodiments, the present precursor composition can include a base, typically, NH₃. In various embodiments, the base can be introduced into the precursor composition after the fuel and the oxidizing reagent have dissolved completely in the solvent or solvent mixture.

Examples of oxidizing anions include, but are not limited to, nitrates, nitrites, perchlorates, chlorates, hypochlorites, azides, N-oxides (R³N⁺—O⁻), peroxides, superoxides, high-valent oxides, persulfates, dinitramides, nitrocyanamides, nitroarylcarboxylates, tetrazolates, and hydrates thereof. As described above, in some embodiments, the oxidizing agent can be in the form of an acid, in which case, the acid can be a corresponding acid of one of the oxidizing anions described herein (e.g., nitric acid). For example, the oxidizing agent can be in the form of an acid in embodiments where the fuel is a metal reagent including a fuel anion.

The fuel in the precursor compositions generally can be described as a compound or anion capable of being oxidized by the oxidizing agent and releasing energy (i.e., heat) by the process of oxidation. This fuel component can be decomposed into one or more intermediates such as COO⁻, CO, CH₄, CH₃O⁻, NH₂NHOH, NH₃, N₂H₃⁻, N₂H₄, and N₂H₅⁺, before conversion into CO₂, H₂O, and optionally, N₂. When the fuel is an organic compound, the organic fuel can be composed of carbon, oxygen, and hydrogen, and in some embodiments, also nitrogen. Other elements can be present in the fuel such as fluorine, sulfur, and phosphorus. Typically, the organic fuel is a relatively low molecular weight compound. For example, the organic fuel can have a molar mass of about 200 g/mol or less. Examples of organic fuel that can be used as one of the precursors according to the present methods include, without limitation, acetylacetone (CH₃COCH₂COCH₃), fluorinated derivatives of acetylacetone (e.g., CF₃COCH₂COCF₃ or CH₃COCHFCOCH₃), imine derivatives of acetylacetone (e.g., CH₃COCH₂C(═NR)CF₃ or CH₃C(═NR)CHFC(═NR)CH₃), phosphine derivatives of acetylacetone (e.g., Ph₂POCH₂COCH₃), urea (CO(NH₂)₂), thiourea (CS(NH₂)₂), glycine (C₂H₅NO₂), alanine (C₃H₇NO₂), N-methylurea (CH₃NHCONH₂), citric acid (HOC(COOH)(CH₂COOH)₂), stearic acid (CH₃(CH₂)₁₆COOH), ascorbic acid, ammonium bicarbonate (NH₄HCO₃), nitromethane, ammonium carbonate ((NH₄)₂CO₃), hydrazine (N₂H₄), carbohydrazide (CO(N₂H₃)₂), oxalyl dihydrazide, malonic acid dihydrazide, tetra formal tris azine (TFTA), hexamethylenetetramine (C₆H₁₂N₄), malonic anhydride (OCH(CH₂)CHO), as well as diamines, diols, or dioic acids having an internal alkyl chain of 6 carbon atoms or less. In embodiments where the fuel component also acts as the metal source, the corresponding ester of the carboxylic acids or anhydrides described herein can be used instead. To illustrate, examples of fuel anions can include, without limitation, acetylacetonates (including fluorinated, imine or phosphine derivatives thereof), oxalates, citrates, ascorbates, stearates, and so forth. Various metal acetylacetonates are commercially available including aluminum (III) acetylacetonate, zinc (II) acetylacetonate, and zirconium (IV) acetylacetonate. Indium (III) acetylacetonate, gallium (III) acetylacetonate, and tin(II) acetylacetonate are known in the literature, as well as various metal oxalates, metal citrates, metal ascorbates, and metal stearates.

Depending on the composition of the desired metal oxides, one or more metal reagents can be present in the precursor composition. Each metal reagent can include a metal selected from a transition metal (any Group 3 to Group 11 metal), a Group 12 metal, a Group 13 metal, a Group 14 metal, a Group 15 metal, and a lanthanide. In certain embodiments, the present precursor composition can include a metal reagent having a metal selected from a Group 13 metal, a Group 14 metal, a Group 15 metal, and a lanthanide. In particular embodiments, the present precursor composition can include at least a Group 13 metal reagent, for example, an indium (In) reagent and/or a gallium reagent (Ga) for preparing an electrically transporting metal oxide such as In₂O₃, IZO, IGO, IGZO, or ITO. In particular embodiments, the present precursor composition can include a Group 13 metal (such as aluminum (Al)) and/or a lanthanide (such as lanthanum (La) or cerium (Ce)) for preparing an insulating metal oxide such as Al₂O₃, CeOₓ, La₂O₃ or LaAlO₃.

In preferred embodiments, the present method is used to prepare an indium-containing metal oxide, for example, In₂O₃, IZO, IGO, IGZO, or ITO. Accordingly, the precursor composition for such embodiments can include an organic fuel selected from acetylacetone (including fluorinated, imine, or phosphine derivatives thereof), urea, N-methylurea, citric acid, stearic acid, ascorbic acid, hydrazine, carbohydrazide, oxalyl dihydrazide, malonic acid dihydrazide, and malonic anhydride; and an indium salt comprising an oxidizing anion selected from a nitrate, a nitrite, a perchlorate, a chlorate, a hypochlorite, an azide, an N-oxide, a peroxide, a superoxide, a high-valent oxide, a persulfate, a dinitramide, a nitrocyanamide, a nitroarylcarboxylate, a tetrazolate, and hydrates thereof. For example, the precursor composition can include In(NO₃)₃ or a hydrate thereof, and an organic fuel such as acetylacetonate, CF₃COCH₂COCF₃, CH₃COCHFCOCH₃, CH₃COCH₂C(═NR)CF₃, CH₃C(═NR)CHFC(═NR)CH₃, Ph₂POCH₂COCH₃, or urea. In other embodiments, an indium-containing metal oxide thin film can be prepared according to the present methods using a precursor composition that can include an indium salt including a fuel anion selected from an acetylacetonate, an oxalate, a citrate, an ascorbate, and a stearate; and an oxidizing agent that is either an acid or an inorganic reagent including an oxidizing anion selected from a nitrate, a nitrite, a perchlorate, a chlorate, a hypochlorite, an azide, an N-oxide, a peroxide, a superoxide, a high-valent oxide, a persulfate, a dinitramide, a nitrocyanamide, a nitroarylcarboxylate, a tetrazolate, and hydrates thereof. For example, the precursor composition can include indium acetylacetonate as the fuel and either nitric acid (HNO₃) or NH₄NO₃ as the oxidizing agent. In yet other embodiments, an indium-containing metal oxide thin film can be prepared according to the present methods using a precursor composition that can include a first indium salt including an oxidizing anion selected from a nitrate, a nitrite, a perchlorate, a chlorate, a hypochlorite, an azide, an N-oxide, a peroxide, a superoxide, a high-valent oxide, a persulfate, a dinitramide, a nitrocyanamide, a nitroarylcarboxylate, a tetrazolate, and hydrates thereof; and a second indium salt including a fuel anion selected from an acetylacetonate (including fluorinated, imine, or phosphine derivatives thereof), an oxalate, a citrate, an ascorbate, and a stearate. In any of these embodiments, the precursor composition can include NH₃.

When mixed oxides (e.g., ternary or quaterny oxides) are desired, the additional metal reagent(s) can comprise any anion that would confer satisfactory solubility to the metal reagent(s) in the solvent or solvent mixture of the precursor composition. Accordingly, the additional metal reagent(s) independently can comprise an oxidizing anion, a fuel anion, or a non-oxidizing anion. Examples of non-oxidizing anions include, but are not limited to, halides (e.g., chlorides, bromides, iodides), carbonates, acetates, formates, propionates, sulfites, sulfates, hydroxides, alkoxides, trifluoroacetates, trifluoromethanesulfonates, tosylates, mesylates, and hydrates thereof. In embodiments where a desired metal is not chemically stable as an oxidizing salt and/or it is not readily available as a salt comprising a fuel anion as described herein, an inorganic reagent comprising an oxidizing anion or a fuel anion can be used. For example, an inorganic reagent that can be used as an oxidizing agent can be selected from ammonium nitrate, ammonium dinitramide, ammonium nitrocyanamide, and ammonium perchlorate. Examples of inorganic reagents that can be used as a fuel can include, without limitation, ammonium acetylacetonate, ammonium oxalate, ammonium ascorbate, ammonium citrate, and ammonium stearate.

In certain embodiments, the precursor composition can include a first metal salt and a second metal salt, wherein the first metal salt comprises a fuel and the second metal salt comprises an oxidizing anion. For example, the precursor composition can include a redox pair including a metal nitrate and a metal acetylacetonate. Various metal acetylacetonates are commercially available including aluminum (III) acetylacetonate, zinc (II) acetylacetonate, and zirconium (IV) acetylacetonate. Indium (III) acetylacetonate, gallium (III) acetylacetonate, and tin(II) acetylacetonate are known in the literature. Other examples of metal salts that can function as a fuel include, but are not limited to, metal oxalates, metal citrates, metal ascorbates, metal stearates, and so forth.

The concentration of metal reagents in the precursor composition can be between about 0.01 M and about 5.0 M. For example, the metal reagent can have a concentration between about 0.02 M and about 2.0 M, between about 0.05 M and about 1.0 M, between about 0.05 M and about 0.5 M, or between about 0.05 M and about 0.25 M. In embodiments in which the precursor composition includes two or more metal reagents, the relative ratio of the metal reagents can vary, but typically ranges from 1 to 10.

The solvent or solvent mixture can include water and/or one or more organic solvents. For example, the solvent can be selected from water, an alcohol, an aminoalcohol, a carboxylic acid, a glycol, a hydroxyester, an aminoester, and a mixture thereof. In some embodiments, the solvent can be selected from water, methanol, ethanol, propanol, butanol, pentanol, hexyl alcohol, heptyl alcohol, ethyleneglycol, methoxyethanol, ethoxyethanol, methoxypropanol, ethoxypropanol, methoxybutanol, dimethoxyglycol, N,N-dimethylformamide, and mixtures thereof. In particular embodiments, the solvent can be an alkoxyalcohol such as methoxyethanol, ethoxyethanol, methoxypropanol, ethoxypropanol, or methoxybutanol.

In some embodiments, the precursor composition further can include a metal oxide nanomaterial. The metal oxide nanomaterial typically can be present in an amount of at least about 50% by weight based on the overall weight of the metal oxide thin film. The redox pair of combustion precursors functions as a binder component for the metal oxide nanomaterial in these embodiments, and can be present in an amount of at least about 10% by weight based on the overall weight of the metal oxide thin film. The resulting nanomaterial-derived metal oxide thin films generally have better electronic properties when compared to metal oxide thin films prepared from identical metal oxide nanomaterials but without the redox pair of combustion precursors described herein as binders. Similarly, the present nanomaterial-derived metal oxide thin films also generally have better electronic properties than those prepared with other organic or inorganic binders known in the art. The use of combustion precursors described herein as a binder can lead to unexpected improvements in conductivity (for electrically conducting metal oxides), charge mobility (for semiconducting metal oxides), or leakage current density (for electrically insulating metal oxides).

As used herein, a “nanomaterial” generally has at least one dimension of about 300 nm or smaller. Examples of nanomaterials include nanoparticles (which can have irregular or regular geometries), nanospheres, nanowires (which are characterized by a large aspect ratio), nanoribbons (which has a flat ribbon-like geometry and a large aspect ratio), nanorods (which typically have smaller aspect ratios than nanowires), nanotubes, and nanosheets (which has a flat ribbon-like geometry and a small aspect ratio). Various metal oxide nanomaterials are commercially available or can be prepared by one skilled in the art. Table 1 below provides examples of metal oxide nanomaterials that can be used according to the present teachings.

TABLE 1

| Composition | Types of Nanomaterials |
|---|---|
| ZnO | nanoparticle, nanorod, nanowire |
| GZO (Gallium doped zinc oxide) | nanoparticle |
| Ga₂O₃ | nanoparticle |
| In₂₋ₓGaₓO₃ | nanoparticle |
| In₂O₃ | nanoparticle, nanorod, nanowire |
| ITO (Tin doped indium oxide) | nanoparticle, nanorod, nanowire |
| SnO₂ | nanoparticle, nanorod, nanowire |
| ATO (Antimony doped tin oxde) | nanoparticle |
| BaTiO₃ | nanoparticle |
| (Ba, Sr)TiO₃ | nanoparticle |
| LiNbO₃ | nanoparticle |
| Fe₂O₃ | nanoparticle |
| Sb₂O₃ | nanoparticle |
| Bi₂O₃ | nanoparticle |
| CuO | nanoparticle |
| Co₃O₄ | nanoparticle |
| ZnFe₂O₄ | nanoparticle |
| PbTiO₃ | nanowire |

The metal oxide nanomaterials can be electrically conducting, electrically insulating, or semiconducting as described hereinabove. The metal oxide nanomaterials can include one or more metals selected from a transition metal (any Group 3 to Group 11 metal), a Group 12 metal, a Group 13 metal, a Group 14 metal, a Group 15 metal, a lanthanide, and combinations thereof.

In various embodiments, the precursor composition can include one or more additives selected from detergents, dispersants, binding agents, compatibilizing agents, curing agents, initiators, humectants, antifoaming agents, wetting agents, pH modifiers, biocides, and bacteriostats. For example, surfactants, chelates (e.g., ethylenediaminetetraacetic acid (EDTA)), and/or other polymers (e.g., polystyrene, polyethylene, poly-alpha-methylstyrene, polyisobutene, polypropylene, polymethylmethacrylate and the like) can be included as a dispersant, a binding agent, a compatibilizing agent, and/or an antifoaming agent.

Metal oxide synthesis using combustion chemistry between a fuel and an oxidizing agent offers many advantages for film solution processing. First, the availability of high local temperatures without a furnace enables low-cost large-scale thin-film syntheses, and the high self-generated energies can convert the precursors into the corresponding oxides at low process temperatures. In contrast, oxide formation via conventional precursors based on sol-gel chemistry conversion is endothermic, and requires significant external energy input to form metal-O-metal lattices, whereas combustion synthesis is exothermic and does not require external energy input once ignited. Furthermore, conventional precursors typically require high temperatures for decomposing the organic stabilizer to achieve phase-pure products, while in combustion reactions with balanced redox chemistry, the atomically local oxidizer supply can remove organic impurities efficiently without coke formation.

The combustion chemistry enabled by the present precursor compositions allows the in situ annealing temperature to be lowered to less than or about 350° C. In various embodiments, the in situ annealing temperature can be less than or about 325° C., less than or about 300° C., less than or about 275° C., less than or about 250° C., less than or about 225° C., less than or about 200° C., less than or about 180° C., or as low as about 150° C. More generally, the in situ annealing temperature can be lower than the dehydration temperature of the desired metal oxide. Table 2 provides the reported dehydration temperature of various metal oxides.

TABLE 2
Metal Hydroxide

| | | |
|---|---|---|
| Mg(OH)₂ | MgO (300° C.) | |
| Al(OH)₃ | AlOOH (300° C.) | Al₂O₃ (500° C.) |
| Si(OH)₄ | a-SiO₂ (600° C.) | |
| Zn(OH)₂ | ZnO (155° C.) | |
| Ga(OH)₃ | Ga₂O₃ (420-500° C.) | |
| Cd(OH)₂ | CdO (360° C.) | |
| In(OH)₃ | In₂O₃ (270-330° C.) | |
| Sn(OH)₄ | SnO₂ (290° C.) | |
| Pb(OH)₂ | PbO (T_{dehyd} < 100° C.) | |
| Y(OH)₃ | YOOH (250° C.) | Y₂O₃ (400° C.) |
| H₂Ti₂O₄(OH)₂ | TiO₂ (400° C.) | |
| ZrOₓ(OH)₄₋₂ₓ | a-ZrO₂ (~200-400° C.) | |
| Ni(OH)₂ | NiO (300° C.) | |
| Cu(OH)₂ | CuO (T_{dehyd} < 120° C.) | |
| Ce(OH)₄ | CeO₂ (T_{dehyd} < 200° C.) | |

For example, the annealing temperature can be at least 25° C., at least 50° C., or at least 70° C. lower than the dehydration temperature of the metal oxide.

The in situ annealing step can be performed by heating the substrate on a hot plate. Once the substrate reaches the desired temperature, the precursor composition can be spray-coated onto the heated substrate using a spray-coating (e.g., airbrush) system. Generally, a spray-coating system can include a reservoir for storing the precursor composition, a compressed gas source attached to the reservoir for atomizing the precursor composition into an aerosol, and a spray nozzle outlet for dispersing the aerosol. The system can be enclosed to control the atmosphere during spraying to promote film formation. Furthermore, the nebulized flux and/or the growing film can be exposed to various radiation (UV, IR) and/or ion-bombardment (O₂ plasma) to further control film microstructure and composition. The precursor composition can be stirred either continuously or intermittently while in the reservoir to maintain its homogeneity. A computer system can be used to control the rate and amount of the precursor composition ejected from the nozzle (for example, by varying the pressure of the compressed gas). In preferred embodiments, the spray-coating step is performed intermittently. For example, spraying can take place for 10 seconds, followed by a pause of about 30 seconds to allow the combustion synthesis reaction to proceed, then another period of spraying for about 10 seconds, and so on, until the desired thickness is obtained. The nozzle can be held at a vertical distance of about 5-100 cm, preferably about 10-30 cm away from the substrate. However, the distance from the substrate can be varied, as can be the shape of the nozzle outlet. For examples, nozzles that provide conical sprays, linear sprays, planar sprays, or other spray geometries can be used.

The present methods can be used to prepare metal oxides of various compositions, including binary oxides and mixed oxides such as ternary oxides. In various embodiments, the metal oxide can include at least one Group 13 metal, at least one Group 14 metal, and/or at least one lanthanide. In certain embodiments, the present methods can be used to prepare a thin film semiconductor comprising an amorphous metal oxide, particularly, an amorphous ternary or quaternary metal oxide. For example, the amorphous metal oxide thin film semiconductor can be selected from α-IZO, α-ZTO, α-IGO, and α-IGZO. In certain embodiments, the present methods can be used to prepare a thin film dielectric comprising an amorphous metal oxide. For example, the amorphous metal oxide can be α-alumina or α-CeO₂. In certain embodiments, the present methods can be used to prepare a thin film conductor comprising a ternary metal oxide selected from ITO and AZO. In most embodiments, the metal oxide thin film can have a film thickness of at least about 20 nm, preferably at least about 40 nm, and most preferably at least about 50 nm. Such film thickness is obtained in a single step according to the present method (i.e., the substrate is not removed from the initial setup).

The metal oxide thin film fabricated according to the present teachings can be used in various types of semiconductor devices. For example, the present metal oxide thin films can be used as semiconductors, dielectrics, and/or conductors in thin film transistors; as transparent conducting metal oxides in light-emitting devices; and as electrodes or interfacial layers (e.g., hole-transport layer (HTL) or electron-transport layer (ETL)) in (bulk-heterojunction (BHJ-OPV) or dye-sensitized (DSSC)) photovoltaic devices.

Accordingly, in one aspect, the present teachings can relate to a method of fabricating a thin film transistor. The thin film transistor can have different configurations, for example, a top-gate top-contact structure, top-gate bottom-contact structure, a bottom-gate top-contact structure, or a bottom-gate bottom-contact structure. A thin film transistor generally includes a substrate, electrical conductors (source, drain, and gate conductors), a dielectric component coupled to the gate conductor, and a semiconductor component coupled to the dielectric on one side and in contact with the source and drain conductors on the other side. As used herein, “coupled” can mean the simple physical adherence of two materials without forming any chemical bonds (e.g., by adsorption), as well as the formation of chemical bonds (e.g., ionic or covalent bonds) between two or more components and/or chemical moieties, atoms, or molecules thereof.

The present methods of fabricating a thin film transistor can include coupling the thin film semiconductor to the thin film dielectric; and coupling the thin film dielectric to the thin film gate electrode. The thin film semiconductor can be coupled to the thin film dielectric by contacting the thin film dielectric with a semiconductor precursor composition, wherein the semiconductor precursor composition can include a fuel and one or more oxidizing agents in a solvent or solvent mixture, wherein the fuel and/or at least one of the oxidizing agent(s) comprise a metal reagent, and wherein the fuel and the one or more oxidizing agents are present in substantially stoichiometric amounts to allow metal oxide formation and complete combustion. For example, the semiconductor precursor composition can include at least one oxidizing metal reagent and a fuel selected from acetylacetone (including fluorinated, imine, or phosphine derivatives thereof), urea, N-methylurea, hydrazine, malonic anhydride, and a metal acetylacetonate. In certain embodiments, the semiconductor precursor composition can include two or more metal reagents, wherein at least one of the metal reagents comprises an oxidizing anion and at least one of the metal reagents comprises a metal selected from a lanthanide, a Group 13 metal, and a Group 14 metal.

The thin film dielectric can be composed of inorganic (e.g., oxides such as SiO₂, Al₂O₃, ZrOₓ or HfO₂; and nitrides such as Si₃N₄), organic (e.g., polymers such as polycarbonate, polyester, polystyrene, polyhaloethylene, polyacrylate), or hybrid organic/inorganic materials. The thin film dielectric can be coupled to the thin film gate electrode by various methods known in the art, including the growth of self-assembled nanodielectric materials such as those described in Yoon et al., PNAS, 102 (13): 4678-4682 (2005), and Ha et al., Chem. Mater., 21(7): 1173-1175 (2009); and solution-processable inorganic/organic hybrid materials as described in Ha et al., J. Am. Chem. Soc., 132 (49): 17428-17434 (2010), the entire disclosure of each of which is incorporated by reference herein. In various embodiments, the thin film dielectric material in contact with a metal oxide thin film semiconductor prepared according to the present teachings can have a high dielectric constant. For example, the thin film dielectric material can have a dielectric constant that ranges from about 4 to about 30. Furthermore, the dielectric material can be in the form of a bilayer, where one layer is composed of an electrically insulating organic layer which is in contact with the metal oxide semiconductor layer according to the present teachings and a second electrically insulating metal oxide layer which can be deposited by solution processing or vapor deposition such as sputtering. In such embodiments, the organic layer can have a dielectric constant between about 2 and about 4, and the oxide layer can have a dielectric constant between about 4 and about 30.

In certain embodiments, the thin film dielectric can be a metal oxide thin film prepared according to the present methods. The implementation of a low-temperature amorphous metal oxide thin film dielectric with a metal oxide thin film semiconductor prepared by the present methods can lead to much improved semiconductor-dielectric interface, which can enhance the transistor performance significantly. Accordingly, in certain embodiments, the thin film gate electrode can be contacted with a dielectric precursor composition, where the dielectric precursor composition can include a fuel and one or more oxidizing agents in a solvent or solvent mixture, wherein the fuel and/or at least one of the oxidizing agent(s) comprise a metal reagent, and wherein the fuel and the one or more oxidizing agents are present in substantially stoichiometric amounts to allow metal oxide formation and complete combustion. For example, the dielectric precursor composition can include at least one metal reagent and an organic fuel in a solvent or solvent mixture, wherein the metal reagent and the organic fuel form a redox pair. In particular embodiments, the metal reagent can comprise aluminum or cerium.

The gate electrode and the other electrical contacts (source and drain electrodes) independently can be composed of metals (e.g., Au, Ag, Al, Ni, Cu), transparent conducting oxides (e.g., ITO, FTO, IZO, ZITO, GZO, GIO, GITO), or conducting polymers (e.g., poly(3,4-ethylenedioxythiophene) poly(styrenesulfonate) (PEDOT:PSS), polyaniline (PANI), or polypyrrole (PPy)). In certain embodiments, the gate electrode (and/or source and drain electrodes) of the thin film transistor can be a metal oxide thin film (e.g., a transparent conducting oxide such as ITO, IZO, ZITO, GZO, GIO, or GITO) prepared according to the present methods (including a nanomaterial-derived metal oxide thin film as described below). Accordingly, in certain embodiments, the method can include coupling the thin film gate electrode to a substrate by contacting the substrate with a conductor precursor composition, where the conductor precursor composition can include a fuel and one or more oxidizing agents in a solvent or solvent mixture, wherein the fuel and/or at least one of the oxidizing agent(s) comprise a metal salt, and wherein the fuel and the one or more oxidizing agents are present in substantially stoichiometric amounts to allow metal oxide formation and complete combustion. In certain embodiments, the conductor precursor composition can include at least two metal reagents and a fuel selected from acetylacetone (including fluorinated, imine, or phosphine derivatives thereof), urea, N-methylurea, hydrazine, malonic anhydride, and a metal acetylacetonate.

The substrate component can be selected from doped silicon, glass, aluminum or other metals alone or coated on a polymer or other substrate, a doped polythiophene, as well as polyimide or other plastics including various flexible plastics. In particular embodiments, the substrate can be a low heat-resistant flexible plastic substrate with which prior art conventional precursors for processing oxide thin films are incompatible. Examples of such flexible substrates include polyesters such as polyethylene terephthalate, polyethylene naphthalate, polycarbonate; polyolefins such as polypropylene, polyvinyl chloride, and polystyrene; polyphenylene sulfides such as polyphenylene sulfide; polyamides; aromatic polyamides; polyether ketones; polyimides; acrylic resins; polymethylmethacrylate, and blends and/or copolymers thereof. In particular embodiments, the substrate can be an inexpensive rigid substrate that has relatively low heat and/or chemical resistance. For example, the present metal oxide thin films can be coupled to an inexpensive soda lime glass substrate, as opposed to more expensive and higher heat and/or chemical resistant glass substrates such as quartz and VYCOR®.

Accordingly, the present teachings also encompass TFT devices that include a substrate (including a substrate-gate material such as, but not limited to, doped-silicon wafer, tin-doped indium oxide on glass, tin-doped indium oxide on mylar film, and aluminum on polyethylene terephthalate), a dielectric material as described herein deposited on the substrate/substrate-gate, a semiconductor material deposited on the dielectric material, and source-drain contacts. In some embodiments, the TFT can be a transparent TFT including one or more of the following: a transparent or substantially transparent substrate, a transparent or substantially transparent gate conductor, a transparent or substantially transparent inorganic semiconductor component, a transparent or substantially transparent dielectric component, and transparent or substantially transparent source and drain contacts. As used herein, “transparent” refers to having at least a 90% transmittance in the visible region of the spectrum, and “substantially transparent” refers to having at least 80% transmittance in the visible region of the spectrum.

In certain embodiments, the present teachings can relate to high-performance metal oxide TFTs fabricated, for example, with the present low temperature-processed metal oxide thin film semiconductor (e.g., In₂O₃ or IGZO) on top of a low-temperature-processed amorphous alumina gate dielectric and ITO gate electrode, using a flexible polymer substrate.

In another aspect, the present teachings can relate to a method of fabricating a photovoltaic device including a substrate, a thin film metal oxide anode, a photoactive component, a thin film metal oxide cathode, and optionally one or more thin film metal oxide interfacial layers which can be deposited between the anode and the photoactive component and/or between the cathode and the photoactive component. In certain embodiments, at least one of the thin film anode and the thin film cathode can be a metal oxide thin film conductor according to the present teachings. A conductor composition including a redox pair of combustion precursors according to the present teachings can be spray-coated on the substrate (directly thereon or with the photoactive component first deposited on the substrate) while the substrate is maintained at an elevated temperature (e.g., less than or about 350° C.) to provide a metal oxide thin film conductor. The redox pair of combustion precursors can include an oxidizing agent such as indium nitrate and an organic fuel such as acetylacetone and/or urea. In some embodiments, the thin film metal oxide thin film interlayer can be a metal oxide thin film prepared according to the present teachings. For example, NiO or α-IZO thin films can be prepared from a redox pair of combustion precursors comprising nickel nitrate or indium nitrate and zinc nitrate together with a fuel such as acetylacetone, and deposited via spray-coating as described herein.

The photoactive component disposed between the thin film anode and the thin film cathode can be composed of a blend film which includes a “donor” material and an “acceptor” material. For bulk heterojunction (BHJ) organic photovoltaic devices, the acceptor material typically is a fullerene-based compound such as C60 or C70 “bucky ball” compounds functionalized with solubilizing side chains. Specific examples include C60 [6,6]-phenyl-C61-butyric acid methyl ester (C₆₀PCBM) or C₇₀PCBM. A common donor material used in BHJ solar cells is poly(3-hexylthiophene) (P3HT), but other conjugated semiconducting polymers suitable as donor materials are known in the art and can be used according to the present teachings. Exemplary polymers can include those described in International Publication Nos. WO 2010/135701 and WO 2010/135723.

The present metal oxide thin films also can be used to enable other types of thin film photovoltaic devices. For example, a dye-sensitized solar cell can include a thin film of mesoporous anatase (TiO₂) prepared according to the present teachings. Specifically, a precursor composition including Ti(NO₃)₄.4H₂O and a fuel such as acetylacetone or urea can be spray-coated onto an FTO-coated glass substrate maintained at a temperature less than about 350° C. to provide an anatase film having a thickness of at least about 50 nm, thereby providing a light-converting anode. The anatase/FTO/glass plate then can be immersed in a sensitizing dye solution (e.g., a mixture including a photosensitive ruthenium-polypyridine dye and a solvent) to infuse the pores within the anatase film with the dye. A separate plate is then made with a thin layer of electrolyte (e.g., iodide) spread over a conductive sheet (typically Pt or Pt-coated glass) which is used as the cathode. The two plates are then joined and sealed together to prevent the electrolyte from leaking.

In addition to thin film transistors and thin film photovoltaic devices, the low temperature-processed metal oxide thin films described herein can be embodied within various organic electronic, optical, and optoelectronic devices such as sensors, capacitors, unipolar circuits, complementary circuits (e.g., inverter circuits), ring oscillators, and the like.

The following examples are provided to illustrate further and to facilitate the understanding of the present teachings and are not in any way intended to limit the invention.

### Example 1

### Preparation of Fuel-Based Metal Oxide Combustion Precursor Solutions

All reagents were purchased from Sigma-Aldrich and used as received unless otherwise noted.

Acetylacetone fuel-based In₂O₃, ZnO, and Ga₂O₃ combustion precursor solutions were prepared with In(NO₃)₃.xH₂O, Zn(NO₃)₂.xH₂O, and Ga(NO₃)₃.xH₂O, respectively, dissolved in 2-methoxyethanol (2M concentration) with acetylacetone and NH₄OH to yield 0.05 M to 0.5 M solutions, and allowed to stir for more than 3 hours at 25° C. Approximately 1 hour prior to spin- or spray-coating, the combustion precursor solutions were combined in the desired molar ratios (70% In and 30% Zn in IZO (In:Zn=1:0.43); and 72.5% In, 7.5% Ga, and 20% Zn in IGZO (In:Ga:Zn=1:0.11:0.29)) and stirred for 1 hour.

### Example 2

### Characterization of Metal Oxide Thin Films Spray-Coated from Fuel-Based Combustion Precursor Solutions

Metal oxide films (including In₂O₃, amorphous indium zinc oxide (IZO) and indium gallium zinc oxide (IGZO)) fabricated at annealing temperatures (Tₐ) ranging from about 200° C. to about 300° C. by the present method, namely, spray-coating and combustion synthesis (SCCS), were characterized and compared against those fabricated by prior art spin-coating/combustion-synthesis, using X-ray diffraction (XRD), atomic force microscopy (AFM), scanning electron microscopy (SEM), X-ray photoelectron spectroscopy (XPS), scanning transmission electron microscopy (STEM) with high angle annular dark field (HAADF), and transmission electron microscopy (TEM).

With respect to the spray-coated (SCCS) films, substrates were maintained at annealing temperatures (Tₐ) ranging from about 200° C. to about 300° C. on a hot plate, while aerosols of a 0.05 M combustion precursor solution of the corresponding metal oxide were sprayed intermittently onto the substrates employing a conventional airbrush held at a vertical distance of about 10-20 cm, depending on the annealing temperature. After a period of 10 s, the spraying process was interrupted for 30 s to allow the combustion synthesis reaction to proceed, and the cycle was repeated until the desired thickness (20 nm or 50 nm) was obtained.

With respect to the comparative spin-coated films, the 0.05 M precursor solutions were spin-coated at 3500 rpm for 30 s, and then annealed on a hot plate for 30 min at annealing temperatures (Tₐ) ranging from about 200° C. to about 300° C. for each layer. This process was repeated multiple times to obtain the desired film thickness (20 nm as a (5 nm×4)-multilayer film and 50 nm as a (5 nm×10)-multilayer film). Note that the time required for the spin-coating process (˜100 min) is ˜12× longer than the SCCS process even for the thinner 20 nm films.

XRD measurements were performed with a Rigaku ATX-G Thin Film Diffraction Workstation using Cu kα radiation coupled to a multilayer mirror. XPS (Omicron ESCA Probe) characterization of In 3d, Ga 3d, Zn 2p, and O 1s signals were monitored on metal oxide/SiO₂ after surface cleaning AFM film morphologies were imaged with a Veeco Dimension Icon scanning Probe Microscope using the tapping mode. SEM images were recorded using a Hitachi S4800-II. For STEM and TEM measurements, samples were prepared on NaCl substrates with either in situ annealing (for SCCS films) or post annealing (for spin-coated films). The annealed samples were then lifted with an OmniProbe nanomanipulator and transferred to a semi-spherical Cu TEM grid. STEM imaging was conducted with a JEOL-2300F microscope, and TEM imaging was conducted with a JEOL-2100F microscope.

Crystallization and Densification of SCCS Metal Oxide Thin Films

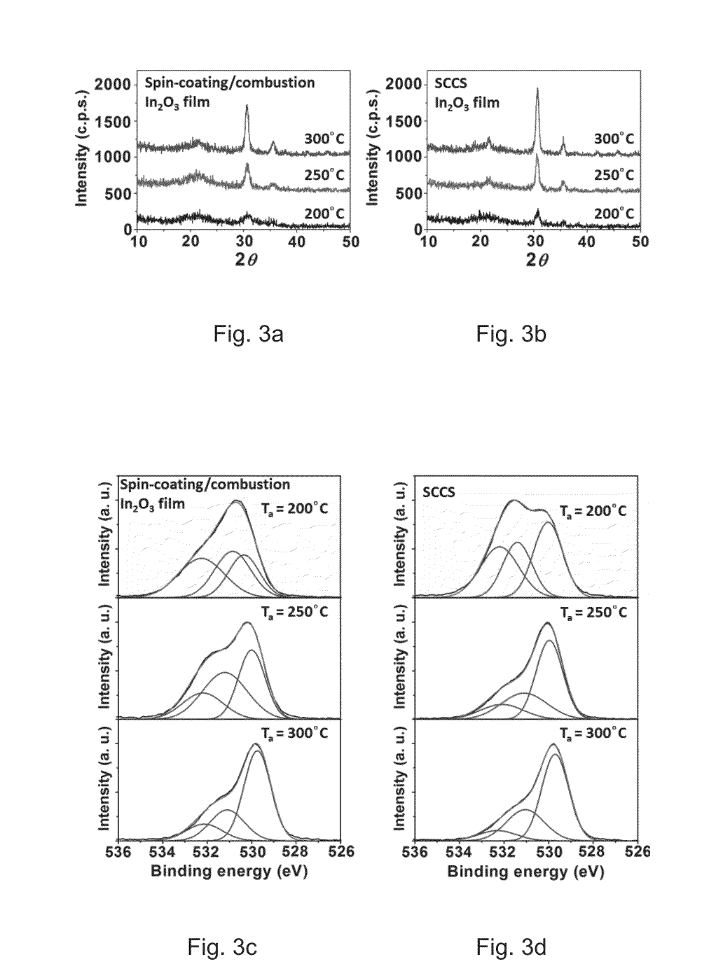

XRD analysis was carried out to elucidate any structural differences between 20-nm oxide films prepared by SCCS versus the conventional spin-coating/combustion method (FIGS. 3a and 3b). Noticeably, SCCS In₂O₃ films exhibit dramatically stronger reflections than those fabricated by spin-coating, indicating enhanced film crystallinity. Not unexpectedly, 20 nm IZO and IGZO films grown at 200-300° C. by both methods are amorphous, consistent with reports in the literature that doping In₂O₃ with Zn²⁺ or Ga³⁺ frustrates crystallization.

XPS was next performed to assess the oxygen bonding states within these films. The O1s spectra reflect three different oxygen environments: M-O-M lattice species at 529.9±0.1 eV; bulk and surface metal hydroxide (M-OH) species at 531.3±0.1 eV; and weakly bound surface adsorbed species, i.e., H₂O or CO₂ at 532.2±0.1 eV. The O1s scan of the In₂O₃ films shown in FIGS. 3c and 3d reveals the evolution of M-O-M characteristics at 529.9 eV with increasing processing temperatures. Moreover, at the same annealing temperature, a higher density of XPS M-O-M lattice species is observed for the SCCS In₂O₃ films versus the spin-coated ones. Similar trends are also observed for SCCS and spin-coated IZO and IGZO films. Without wishing to be bound by any particular theory, the inventors believe that the improved structural and chemical features of the SCCS oxide films versus the spin-coated films can be attributed to the enhanced combustion efficiency enabled by the SCCS method.

Surface Morphology of SCCS Metal Oxide Thin Films

As previously reported, while spin-coated metal oxide films prepared from combustion precursor solutions can achieve very smooth surface topographies if they are fabricated as sufficiently thin single-layer films and multilayers (no more than about 20 nm in thickness per layer), thicker single-layer films become more porous and rougher, with root mean square (RMS) roughnesses similar to what are commonly observed in conventional sol-gel oxide films. See e.g., Kim et al., “Low-temperature fabrication of high-performance metal oxide thin-film electronics via combustion processing,” Nat. Mater., 10: 382-388 (2011).

By comparison, using the present SCCS method, smooth, dense, and contiguous single-layer oxide films having a thickness of greater than or about 50 nm can be obtained as observed in AFM and SEM images.

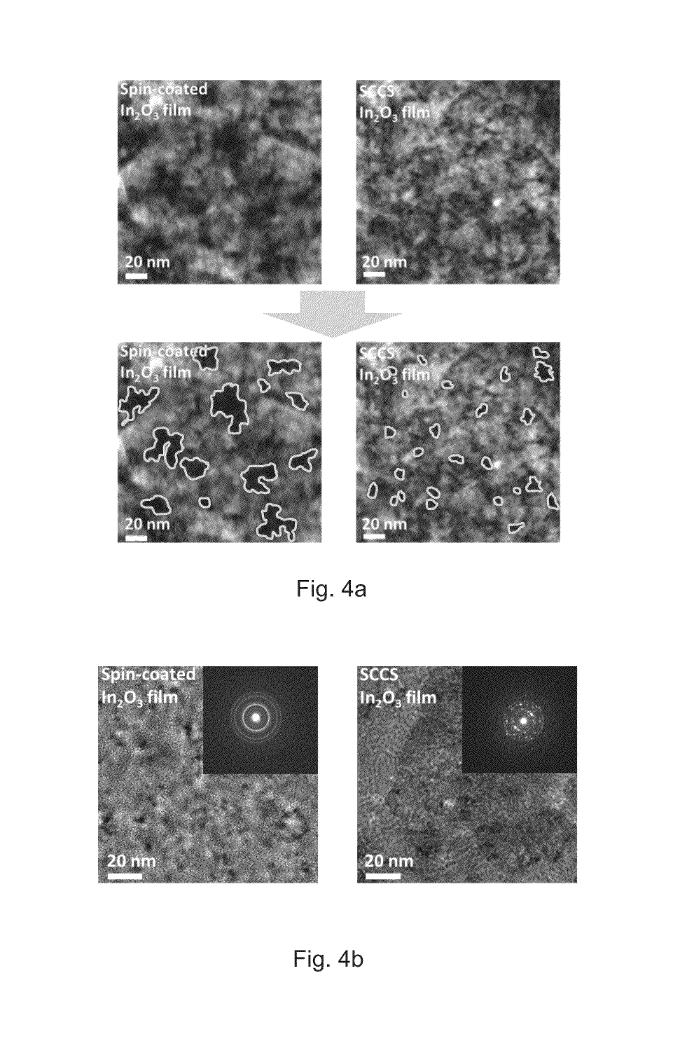

HAADF images further elucidate the film porosity of SCCS films as compared to spin-coated/combustion films (FIG. 4a). In FIG. 4a, because HAADF imaging is insensitive to diffraction and phase contrast, the dark contrast denotes areas of lower mass density than the surrounding gray or white matrix. Thus, the spatially distributed “dark-gray-white” contrast indicates that the films deposited by both spin-coating/combustion and SCCS are nanoporous. However, it can be seen that the SCCS film shows smaller pore size (pores are highlighted in the bottom set of figures for emphasis). Without wishing to be bound by any particular theory, it is believed that while heat is generated rather suddenly during the post annealing step in the spin-coating/combustion method, which can lead to more abrupt emission of gaseous by-products, for the SCCS method, gas accumulation in the film is more suppressed due to simultaneous film growth and in situ annealing, thus affording smoother film surfaces, smaller pore size, and denser films when compared to spin-coated films of the same thickness. Note this was the case even if the spin-coated film was prepared as a multilayer film (5 nm×4).

Thicker, specifically, 50-nm films fabricated via the SCCS method (single-layer) and the spin-coated/combustion method (5 nm×10-multilayer) were characterized and compared. The SCCS films exhibit smooth surfaces with RMS<0.8 nm. Bright field TEM images of spin-coated and SCCS In₂O₃ films at Tₐ=300° C. are shown in FIG. 4b, along with the typical selected area energy-filtered nano-beamed diffraction (EF-NBD) patterns (inset). From the TEM images, it can be seen that the SCCS-deposited In₂O₃ film is more crystalline than that fabricated by spin-coating.

### Example 3

### Transistor Fabrication and Electrical Performance

The electronic properties of the present metal oxide thin films were evaluated in metal oxide thin film transistors (MO TFTs). A top-contact bottom-gate TFT device structure was used. Specifically, SCCS-coated In₂O₃, IZO, and IGZO TFTs were fabricated at various processing temperatures with 20-nm or 50-nm semiconductor layers. Similar spin-coated In₂O₃, IZO, and IGZO TFTs were fabricated as comparative devices.

Doped silicon substrates with 300 nm thermal SiO₂ layers (WRS Materials; solvent cleaned and then cleaned with an O₂ plasma for 5 min) were used as the gate electrode and dielectric layer, respectively. In₂O₃, IZO, and IGZO combustion precursor solutions were deposited by SCCS (or by spin-coating for the comparative devices). For the ZrOₓ dielectric TFTs, amorphous ZrOₓ dielectric films were grown by dissolving ZrCl₄ and Zr(OCH(CH₃)₂)₄(CH₃)₂CHOH in 2M concentration to form a 0.1 M solution, then spin-coating the solution onto the substrate. Finally, 40 nm Al source and drain electrodes were thermally evaporated onto the MO films through a shadow mask. The channel length and width for all devices in this study were 50 and 1000 μm, respectively.

TFT characterization was performed under ambient conditions on a custom probe station using an Agilent 1500 semiconductor parameter analyzer. The charge carrier mobility μ was evaluated in the saturation region with the conventional metal-oxide-semiconductor field effect transistor (MOSFET) model in equation (1) below:

I_{DS}=(WCᵢ/2L)μ(V_{GS}−V_{T})² (1)

where Cᵢ is the capacitance per unit area of insulator, V_{T} is the threshold voltage, and V_{GS} is the gate voltage. W and L are the channel width and length, respectively.

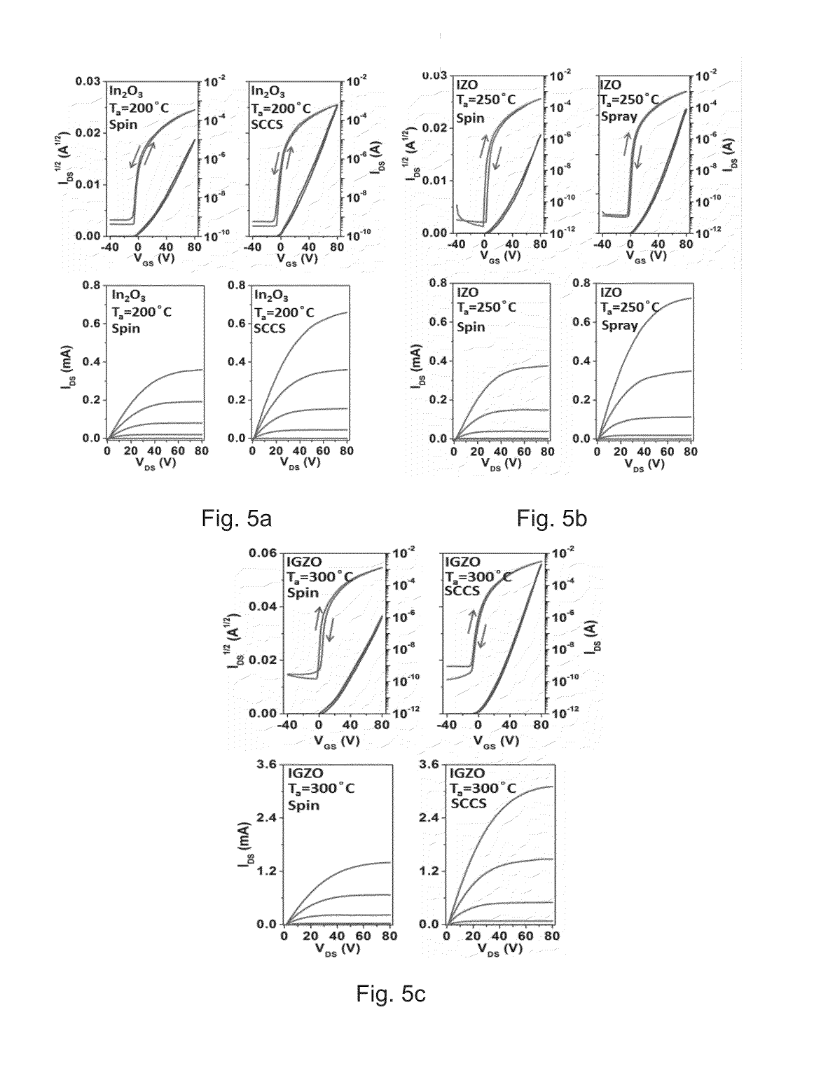

The transfer and output characteristics for representative devices are shown in FIGS. 5a, 5b and 5c and summarized in Table 3 below, while FIG. 5d presents device statistics of more than 20 TFTs fabricated under identical conditions.

TABLE 3
Performance metrics^{a,b} of spin-coated and SCCS 20 nm In₂O₃, IZO, and IGZO
TFTs on 300 nm SiO₂/Si substrates with 40 nm Al source and drain electrodes, after
various processing temperatures.

| Metal | | Mobility | | Metal | | Mobility | |
|---|---|---|---|---|---|---|---|
| oxide | Tₐ (° C.) | (cm²/Vs) | Iₒₙ/I_{off} | oxide | Tₐ (° C.) | (cm²/Vs) | Iₒₙ/I_{off} |
| Spin-coating (4 × 5 nm MO) TFTs | | | | SCCS (20 nm MO) TFTs | | | |
| In₂O₃ | 200 | 0.83 ± 0.17 | 10⁵~10⁶ | In₂O₃ | 200 | 1.44 ± 0.22 | 10⁵~10⁶ |
| | 225 | 1.87 ± 0.27 | 10⁵~10⁶ | | 225 | 3.15 ± 0.23 | 10⁵~10⁶ |
| | 250 | 3.24 ± 0.41 | 10⁴~10⁵ | | 250 | 6.11 ± 0.49 | 10³~10⁴ |
| | 300 | 6.57 ± 0.85 | 10³~10⁴ | | 300 | 15.45 ± 1.03 | 10³~10⁴ |
| Spin-coating TFTs | | | | SCCS TFTs | | | |
| IZO | 225 | 0.29 ± 0.05 | 10⁶~10⁷ | IZO | 225 | 0.52 ± 0.06 | 10⁶~10⁷ |
| | 250 | 0.95 ± 0.18 | 10⁶~10⁸ | | 250 | 2.06 ± 0.26 | 10⁶~10⁷ |
| | 300 | 3.18 ± 0.51 | 10⁶~10⁸ | | 300 | 8.05 ± 0.53 | 10⁶~10⁷ |
| IZO^{c} | | | | | 300 | 81.5 ± 5.66 | 10⁴~10⁵ |
| IGZO | 225 | 0.01 ± 0.005 | 10⁵~10⁶ | IGZO | 225 | 0.18 ± 0.05 | 10⁵~10⁶ |
| | 250 | 0.77 ± 0.14 | 10⁶~10⁸ | | 250 | 1.97 ± 0.26 | 10⁶~10⁷ |
| | 300 | 3.13 ± 0.54 | 10⁸ | | 300 | 6.34 ± 0.69 | 10⁶~10⁷ |
| IGZO^{c,d} | | | | | 300 | 17.8 ± 1.34 | 10⁴~10⁵ |

^{a}Average of ≧20 devices.
^{b}Measured in ambient, RH = 20-30%.
^{c}Using 45 nm ZrOx/ITO substrates.
^{d}IGZO 1:0.11:0.29.

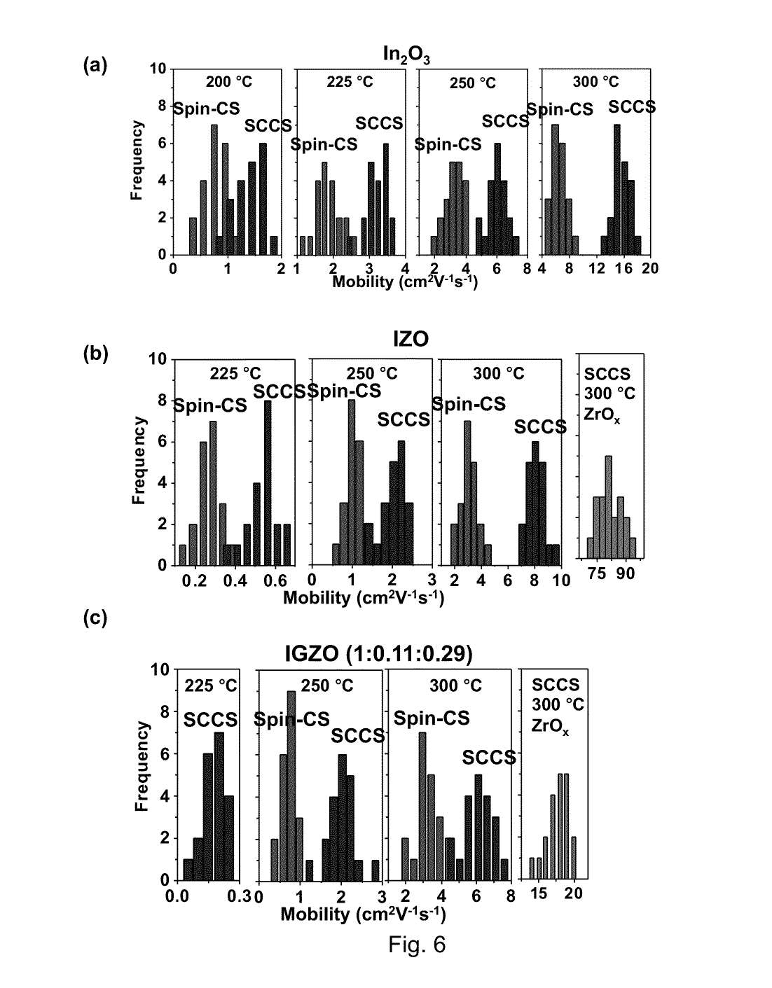

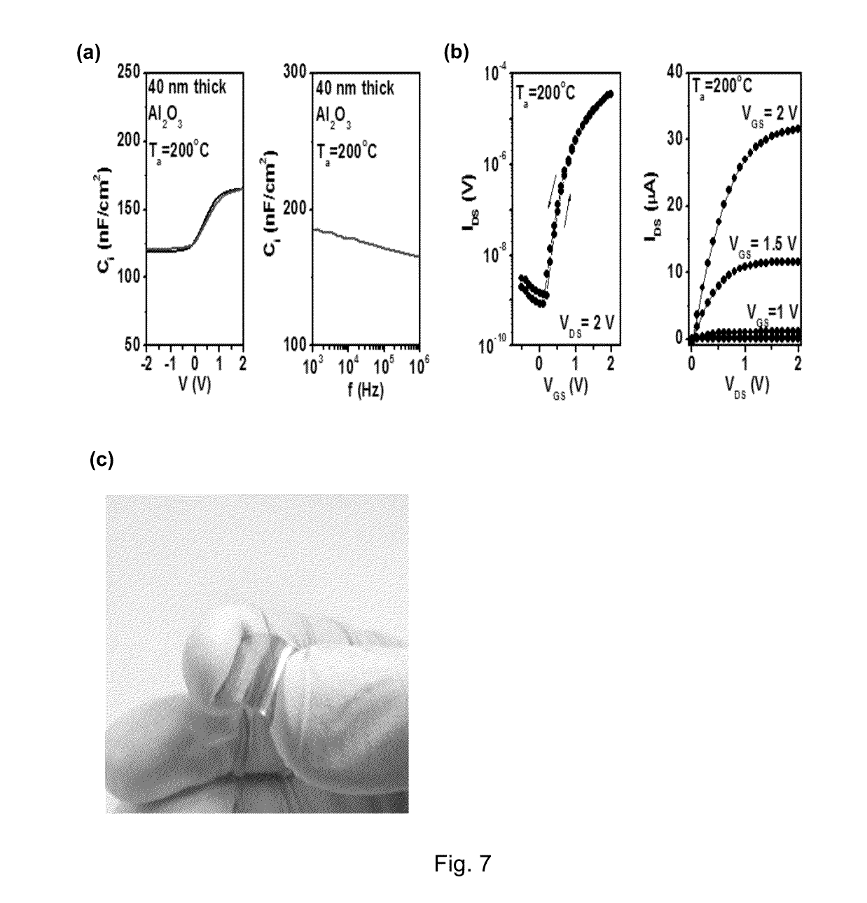

As shown in Table 3 and FIG. 5, the performance of SCCS TFTs is significantly greater than that of spin-coated devices processed at the same temperatures. For example, the highest SCCS In₂O₃ TFT mobility of ˜1.93 cm²V⁻¹s⁻¹ (average ˜1.44 cm²V⁻¹s⁻¹) was obtained at 200° C., which is more than 2× greater than that of spin-coated In₂O₃ devices fabricated at the same temperature, and exceeds typical performance values of a-Si:H based TFTs. When the annealing temperature is increased to 300° C., the In₂O₃ TFT mobility dramatically increases to 18.2 cm²V⁻¹s⁻¹ (average ˜15.45 cm²V⁻¹s⁻¹). Similarly, the mobilities of SCCS IZO (μₘₐₓ˜9.47 cm²V⁻¹s⁻¹, μ_{avg} 8.05 cm²V⁻¹s⁻¹) and IGZO (μₘₐₓ˜7.53 cm²V⁻¹s⁻¹, μ_{avg} 6.34 cm²V⁻¹s⁻¹) TFTs (all processed at ˜300° C.) also are considerably enhanced versus those of the corresponding spin-coated devices (μₘₐₓ=7.43 cm²V⁻¹s⁻¹ for In₂O₃, μₘₐₓ=3.69 cm²V⁻¹s⁻¹ for IZO, and μₘₐₓ=3.65 cm²V⁻¹s⁻¹ for IGZO) despite the >10× reduction in MO film growth time. Furthermore, introducing a solution-processed high-k ZrO₂ dielectric, increases the IZO SCCS μₘₐₓ to 93.4 cm²V⁻¹s⁻¹ with Iₒₙ/I_{off}>10⁵ at low operating voltages of 2V. Without wishing to be bound by any particular theory, the enhanced performance observed in the SCCS TFTs versus the spin-coated/combustion TFTs is believed to be attributable to more extensive M-O-M lattice densification, oxygen vacancy generation pre-filling trap sites, and distortional relaxation reducing trap sites. Note also that despite the simple spray setup, the SCCS-deposited TFT device metrics have significantly lower standard deviations (<15%), indicating greater TFT uniformity, hence the greater reproducibility needed for large-scale fabrication (FIG. 6).

In further comparative experiments, three different groups of IGZO TFTs with 50-nm oxide films were fabricated and characterized. The three different groups are: (i) spin-coated 50-nm single-layer TFTs (realized by varying the precursor concentration and spin rate), (ii) spin-coated 5 nm×10 multi-layer TFTs, and (iii) SCCS 50-nm single-layer TFTs. Their respective performance is summarized in Table 4 below.

TABLE 4
Performance metrics of 50 nm In₂O₃, IZO, and IGZO TFTs on
300 nm SiO₂/Si substrates with 40 nm Al source and drain
electrodes, deposited by various methods: (i) 50-nm single-layer
oxide by spin-coating, (ii) 5 nm × 10 multi-layer oxide by spin-
coating, and (iii) 50-nm single-layer oxide by SCCS. Processing
temperatures are 250° C. and 300° C.

| | Mobility | | Mobility | Iₒₙ/ |
|---|---|---|---|---|
| | (cm²/Vs) | Iₒₙ/I_{off} | (cm²/Vs) | I_{off} |
| Deposition Method | Tₐ = 250° C. | | Tₐ = 300° C. | |
| In₂O₃ | | | | |
| Spin-coating single layer 50 nm | 0.21 | 10⁶ | 0.67 | 10⁶ |
| Spin-coating 5 nm × 10 | 5.08 | 10⁴ | 10.67 | 10⁴ |
| SCCS 50 nm | 10.02 | 10⁴ | 21.56 | 10⁴ |
| IZO | | | | |
| Spin-coating single layer 50 nm | 10⁻⁴ | 10³ | 10⁻² | 10⁵ |
| Spin-coating 5 nm × 10 | 1.84 | 10⁷ | 5.46 | 10⁷ |
| SCCS 50 nm | 4.53 | 10⁷ | 13.22 | 10⁶ |
| IGZO | | | | |
| Spin-coating single layer 50 nm | 10⁻⁴ | 10³ | 10⁻² | 10⁵ |
| Spin-coating 5 nm × 10 | 1.36 | 10⁷ | 4.06 | 10⁷ |
| SCCS 50 nm | 2.91 | 10⁷ | 8.17 | 10⁷ |

As a result of the low combustion efficiency for thicker films, the 50-nm spin-coated single-layer TFTs show poor performance (μ˜10⁻² cm²V⁻¹s⁻¹ for 300° C. processing). In contrast, the 50-nm SCCS single-layer TFTs obtained much higher mobility (highest: ˜9.61 cm²V⁻¹s⁻¹; average: ˜8.17 cm²V⁻¹s⁻¹ for 300° C. processing), which is almost 4 orders of magnitude greater than the 50-nm spin-coated/combustion single layer devices, and more than 2× higher than that of the 5 nm×10 spin-coated/combustion TFTs. As shown in Table 4, the mobilities of 50 nm SCCS In₂O₃ TFTs can achieve up to 25.38 cm²V⁻¹s⁻¹ (average mobility ˜21.56 cm²V⁻¹s⁻¹) at Tₐ=300° C., which, to the inventors' knowledge, is the highest mobility reported for a solution-processed oxide TFT fabricated on Si/SiO₂ substrates at 300° C.

In addition to better performance (as demonstrated by higher mobility and greater reproducibility), it should be noted that the SCCS technique affords significantly reduced device fabrication time compared to the spin-coating technique, which is extremely important for scale-up production. For example, a 50-nm IGZO TFT film was deposited by SCCS in ˜13 min, while a spin-coated 50-nm IGZO TFT film required multiple cycles of deposition (5 nm×10). This resulted in total device fabrication time that is ˜10-20 times longer than the SCCS process. Even with the longer fabrication time, the resulting spin-coated multilayer film still yielded lower mobilities, presumably due to poor control of interfacial bulk trap states.

### Example 4

### Fabrication of Flexible Metal Oxide TFTs

Additional devices were fabricated to investigate compatibility of the present SCCS-processed oxide semiconductors with alternative dielectric and substrate materials. Specifically, flexible metal oxide TFTs were fabricated on Arylite™ polyester substrates using the SCCS method (FIG. 6) with solution-processed Al₂O₃ as the dielectric. Amorphous Al₂O₃ dielectric films were grown by dissolving Al(NO₃)₃.xH₂O in 2M concentration to form a 0.1 M solution, then spin-coating the solution onto Al-coated Arylite™ polyester and annealing at 200° C. for 30 min for each layer, followed by 1 min O₂ plasma treatment. The resulting Arylite™/Al(gate)/Al₂O₃/In₂O₃/Al(source/drain) devices afford favorable performance with μ˜11 cm²V⁻¹s⁻¹, V_{T}=0.6 V, and Iₒₙ/I_{off}˜10⁴ when processed at 200° C., indicating that low temperature-processed, high performance (μ>10 cm²V⁻¹s⁻¹) flexible MO TFTs can be realized by using SCCS.

### Example 5

### Comparison of Single-Layer (50 Nm Thick) IGZO TFTs Fabricated by SCCS, Spin-Coating with Combustion Precursors, Spray-Coating without Fuel, Spin-Coating with Conventional Sol-Gel Precursors and Sputtering from Metal Targets

Further experiments were conducted to compare the electrical performance and stability of SCCS-processed single-layer (50 nm thick) IGZO TFTs against those that were prepared via spin-coating with combustion precursors (“Spin-CS”), spin-coating with conventional sol-gel precursors (“Sol-Gel”), spray-coating without fuel reactants (“Spray”), and sputtering from metal targets (“Sputter”). The thickness 50 nm was chosen for the IGZO films because this is the minimum thickness required for industrial IGZO TFT manufacture and the SCCS process significantly reduces device fabrication time. On a laboratory scale, 50-nm thick IGZO films can be grown by SCCS in about 20 minutes, which is comparable to typical sputtering time excluding chamber evacuation. By comparison, the multiple spin/annealing cycles used in the combustion synthesis spin-coating method and the conventional sol-gel method typically require 4 hours or longer.

Specifically, precursor compositions for the SCCS and Spin-CS methods were prepared with In(NO₃)₃.xH₂O, Zn(NO₃)₂.xH₂O, and Ga(NO₃)₃.xH₂O in 2-methoxyethanol to yield 0.05 M or 0.5 solutions. For 0.05 [or 0.5] M solutions, 55 [or 110] μL NH₄OH and 100 [or 200] μL acetylacetone were added to 10 [or 2] mL of the metal solutions and stirred overnight at 25° C. Prior to spin- or spray-coating, the precursor compositions were combined in the desired molar ratios and stirred for 2 hours. All depositions were carried out at RH<30%.

SCCS: The substrates were maintained at either 300° C. or 350° C. on a hot plate while 0.05M precursor solutions were loaded into the spray gun and sprayed intermittently (60s cycle) on the substrates until the desired thickness (50 nm) was obtained. The nozzle-substrate distance was 10-30 cm.

Spin-CS: For one-step 50 nm single layer devices, precursor solutions with concentrations of 0.5M were spin-coated at 2000 rpm for 60 seconds, and then annealed for 30 minutes at either 300° C. or 350° C.

Spray: The precursor solution and coating process were identical to those of SCCS but without acetylacetone.

Sol-Gel: Precursor compositions were prepared with In(NO₃)₃.xH₂O, and Ga(NO₃)₃.xH₂O in 2-methoxyethanol with a concentration of 0.5M, and then stirred overnight at 25° C. Prior to spin-coating, the precursor solutions were combined in the desired molar ratios and stirred for 2 hours. For one-step 50 nm single layer films, the precursor solutions were spin-coated at 2000 rpm for 60 seconds, and then annealed for 30 minutes at either 300° C. or 350° C.

Sputtering: 50 nm IGZO films were sputtered (1:1:1 target from Nikko Denko) using magnetron-sputtering equipment (AIA International) with a base pressure of <10⁻⁵ torr and an Ar/O₂ mixture (20 sccm:1 sccm) as the carrier gas. After sputtering, the films were annealed at 350° C. for 60 minutes.

Doped silicon substrates with 300 nm thermal SiO₂ layers (WRS Materials; pre-cleaned with deionized water, acetone, and IPA solvents for 10 minutes each, and then cleaned with an O₂ plasma for 5 minutes) were used as the gate electrode and dielectric layer, respectively, for the majority of devices. Additional devices were made with ZrOₓ as the dielectric, in which amorphous ZrOₓ dielectric films were grown by dissolving ZrCl₄ and Zr(OCH(CH₃)₂)₄(CH₃)₂CHOH in 2M concentration to form a 0.1 M solution, then spin-coating the solution onto the doped silicon substrate. After the deposition of the IGZO semiconductor layer (see above), 40 nm Al source and drain electrodes were thermally evaporated through a shadow mask onto the IGZO films. The channel length and width were 50 and 1000 μm, respectively.

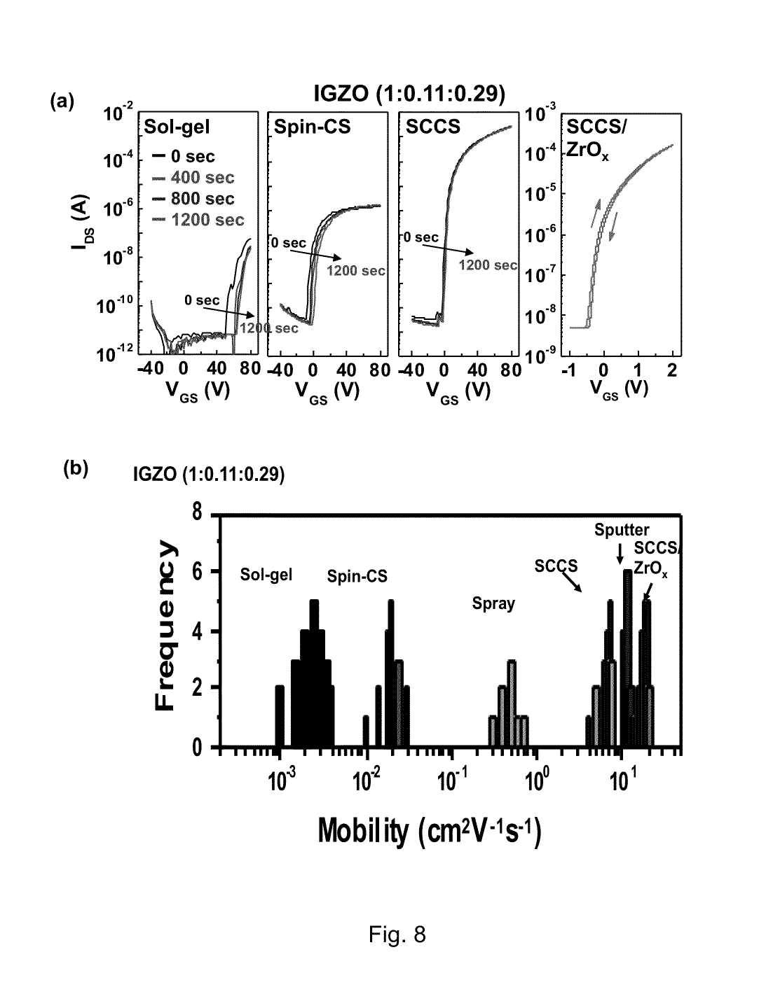

FIG. 8 compares the transfer characteristics, bias stress data, and mobility distribution statistics for the 50 nm-thick single-layer IGZO TFTs fabricated by the different deposition methods and processed at 300° C. Performance metrics are summarized in Table 5 below.

Referring to FIG. 8 and Table 5, it can be seen that the Sol-Gel TFT performance was poor (μ˜10⁻³ cm²V⁻¹s⁻¹), confirming that conventional sol-gel precursors require annealing temperature higher than 300° C. to achieve film densification and reasonable performance TFTs. Single-layer Spin-CS IGZO TFTs also exhibited poor performance (μ˜10⁻² cm²V⁻¹s⁻¹) when annealed at 300° C., confirming that combustion precursors when deposited using spin-coating require multiple deposition/annealing cycles to achieve thicker films and good TFT performance. In contrast, maximum mobilities of 7.6 cm²V⁻¹s⁻¹ and Iₒₙ:I_{off}˜10⁸ were obtained for SCCS IGZO TFTs. Such mobilities are ˜10³-10⁴ times greater than those for the Sol-Gel and Spin-CS devices, and approaching that of sputtered 1:1:1 IGZO devices (μ_{average}=10.9 cm²V⁻¹s⁻¹, μₘₐₓ=12.8 cm²V⁻¹s⁻¹, Iₒₙ:I_{off}˜10⁸, Tₐ=300° C.). The sputtered IGZO device metrics are typical values achieved in fabrication lines using a 300 nm thick SiOₓ layer. Note that IGZO TFTs fabricated by spray pyrolysis using the precursor compositions that have the same metals as SCCS and Spin-CS methods but without the fuel reactants (Spray) performed poorly (μ_{average}=0.53 cm²V⁻¹s⁻¹, μₘₐₓ=0.71 cm²V⁻¹s⁻¹), clearly demonstrating that combustion synthesis is essential for achieving high-quality, thick IGZO films by spray techniques. Finally, using a high-k ZrO₂ dielectric, SCCS μₘₐₓ increased to 21.3 cm²V⁻¹s⁻¹ with Iₒₙ/I_{off}˜10⁵ at 2V TFT operation (FIG. 8b).

Next, solution-processed IGZO films with In:Ga:Zn=1:1:1 and annealing conditions (350° C.) identical to typical commercial sputtering protocols, were investigated. The 1:1:1 In:Ga:Zn composition is seldom studied for solution-processed IGZO TFTs because large Ga contents are known to degrade TFT function when processing temperatures of <500° C. are used. TFTs based on 50 nm thick sputtered, Sol-Gel, Spin-CS, and SCCS IGZO films on Si/SiO₂ substrates were fabricated.

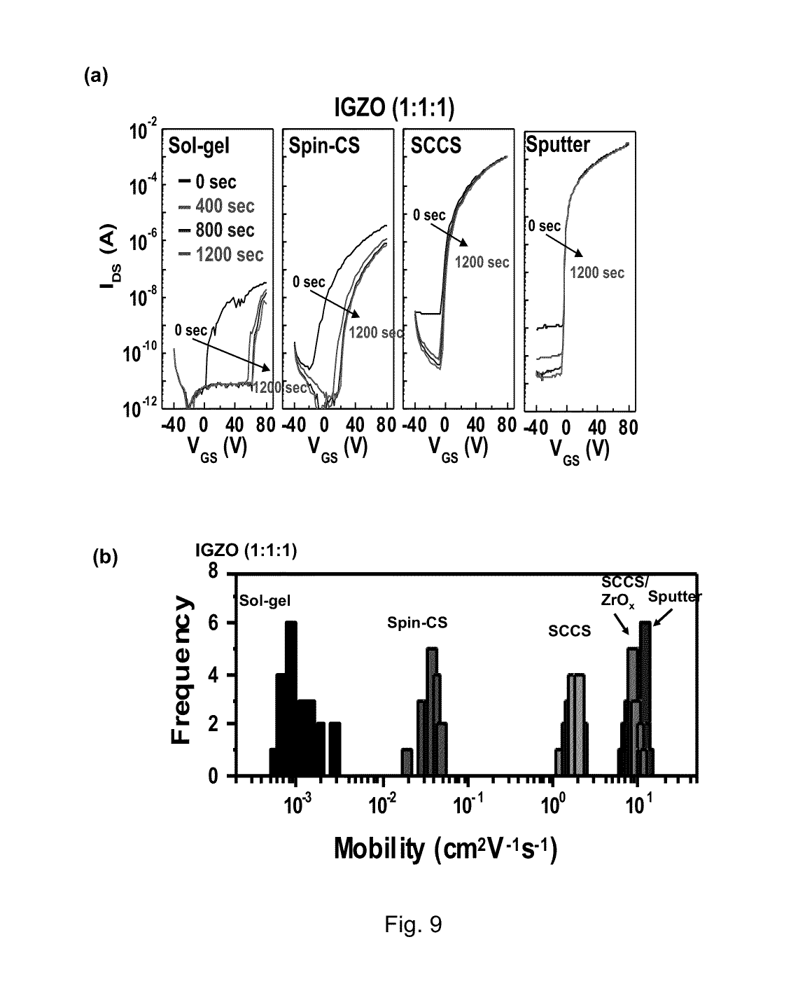

FIG. 9 compares the transfer characteristics, bias stress data, and mobility distribution statistics for the 50 nm-thick single-layer (1:1:1) IGZO TFTs fabricated by the different deposition methods and processed at 350° C. Performance metrics are summarized in Table 5 below.

Not unexpectedly, the Sol-Gel and Spin-CS devices performed poorly (μ˜10⁻³ cm²V⁻¹s⁻¹ for Sol-Gel and μ˜10⁻² cm²V⁻¹s⁻¹ for Spin-CS) even with annealing at 350° C., whereas the SCCS devices exhibited μₘₐₓ=2.3 cm²V⁻¹s⁻¹, Iₒₙ:I_{off}˜10⁶, V_{T}˜16V, and SS˜3V/dec. For 1:1:1 SCCS IGZO with a ZrO₂ gate dielectric, μₘₐₓ=10.7 cm²V⁻¹s⁻¹. To the inventors' knowledge, this is the first report of low-temperature solution-processed IGZO TFTs with a 1:1:1 In:Ga:Zn composition that have a charge carrier mobility of greater than 10 cm²V⁻¹s⁻¹.

Finally and importantly, TFT bias stress stability under identical protocols was investigated (FIGS. 8a and 9a) and, independent of composition, the Sol-Gel and Spin-CS devices exhibited marked threshold voltage shifts (ΔV_{T}>+20˜60V), implying large densities of trap states, whereas the corresponding shifts on for SCCS TFTs (ΔV_{T, 1:0.11:0.29}=+1.3V; ΔV_{T, 1:1:1}=+1.8V) and fully optimized sputtered TFTs (ΔV_{T}=+0.7V) are similar and small. These results are impressive considering that neither patterning of the gate nor of the IGZO layer, or a passivation layer were employed in these devices.

TABLE 5
Performance metrics^{a,b} of 50 nm single layer IGZO TFTs on 300 nm SiO₂/Si
substrates with Al source/drain electrodes fabricated by the indicated methods at 300° C.
(IGZO 1:0.11:0.29) and 350° C. (IGZO 1:1:1).

| | IGZO 1:0.11:0.29 | | | | IGZO 1:1:1 | | | |
|---|---|---|---|---|---|---|---|---|
| Deposition | Mobility | V_{T} | V_{ON} | | Mobility | V_{T} | V_{ON} | |
| Method | (cm²/Vs) | (V) | (V) | Iₒₙ/I_{off} | (cm²/Vs) | (V) | (V) | Iₒₙ/I_{off} |
| Sol-gel | 2.3 × 10⁻³ ± | 58.7 ± 9.6 | 51.6 ± 9.9 | 10³~10⁴ | 1.1 × 10⁻³ ± | 47.1 ± 11.4 | 31.1 ± 10.9 | 10³~10⁴ |
| | 3.0 × 10⁻⁴ | | | | 2.3 × 10⁻⁴ | | | |
| Spin-SC | 1.9 × 10⁻² ± | 31.9 ± 9.5 | 23.7 ± 9.8 | 10⁴~10⁵ | 3.7 × 10⁻² ± | 35.5 ± 8.1 | 2.4 ± 8.9 | 10⁴~10⁵ |
| | 2.1 × 10⁻³ | | | | 2.4. × 10⁻³ | | | |
| Spray | 0.53 ± 0.2 | 7.6 ± 6.5 | −3.3 ± 6.3 | 10³~10⁴ | — | — | — | — |
| Sputter | — | — | — | — | 10.9 ± 0.12 | 2.2 ± 1.9 | −5.8 ± 1.7 | 10⁶~10⁸ |
| SCS | 6.8 ± 0.97 | 5.7 ± 2.8 | −4.1 ± 2.5 | 10⁶~10⁷ | 1.8 ± 0.24 | 15.6 ± 4.0 | −5.3 ± 3.7 | 10⁶~10⁷ |
| SCS^{c} | 19.1 ± 1.58 | 0.05 ± 0.04 | −0.49 ± 0.04 | 10³~10⁵ | 8.4 ± 0.99 | 0.54 ± 0.08 | −0.17 ± 0.07 | 10⁶~10⁷ |

^{a}Average of ≧20 devices (except for spray, 10 devices).
^{b}Measured in ambient, RH = 20-30%.
^{c}Using 45 nm ZrOₓ/ITO substrates.

### Example 6

### Fabrication of SCCS-Processed Metal Oxide Conductors

To demonstrate generality, ˜100 nm thick conducting ITO films were fabricated by SCCS on glass. First, combustion precursor compositions were prepared by dissolving In(NO₃)₃ and SnCl₂ in 2 methoxyethanol to achieve a 0.1 M solution with In:Sn=7:3 molar ratio, followed by addition of acetylacetone and NH₄OH. The 0.1M combustion precursor solutions were then loaded into a spray gun and sprayed intermittently (60 s cycle) to glass substrates maintained at 300° C. on a hot plate until the desired thickness (˜100 nm) was obtained. Comparative Sol-Gel and Spin-CS ITO films were prepared. Sol-Gel ITO films were spin-coated from sol-gel precursor compositions including only In(NO₃)₃ and SnCl₂ in 2 methoxyethanol (0.1 M, In:Sn=7.3). Both Sol-Gel and Spin-CS ITO films were spin-coated at 2000 rpm for 30 seconds, then annealed at 300° C. for 30 minutes, and the desired thickness of ˜100 nm was achieved by repeating the deposition/annealing cycle multiple times.

The conductivities of ITO films were calculated from the equation σ=1/(Rt), where R is the sheet resistance and t is the film thickness. Film thicknesses were determined by profilometer, and the sheet resistance were measured by the four point method.

Similar to results obtained for thin film IGZO semiconductors, ITO films fabricated by the SCCS method exhibited higher conductivities (σ˜180 S/cm) compared to Spin-CS ITO films (σ˜130 S/cm) and Sol-Gel ITO films (σ˜80 S/cm).

The present teachings encompass embodiments in other specific forms without departing from the spirit or essential characteristics thereof. The foregoing embodiments are therefore to be considered in all respects illustrative rather than limiting on the present teachings described herein. Scope of the present invention is thus indicated by the appended claims rather than by the foregoing description, and all changes that come within the meaning and range of equivalency of the claims are intended to be embraced therein.

What is claimed is:

1. A method of fabricating a metal oxide thin film transistor comprising a thin film metal oxide semiconductor, the method comprising forming the thin film metal oxide semiconductor by contacting a substrate with an aerosol of a semiconductor precursor composition while maintaining the substrate at a temperature ranging between about 100° C. and about 350° C., wherein the semiconductor precursor composition comprises a fuel and one or more oxidizing agents in a solvent or solvent mixture, and wherein the fuel and/or at least one of the oxidizing agent(s) comprises a metal salt comprising indium and the fuel and the one or more oxidizing agents are present in amounts to allow metal oxide formation and complete combustion of the fuel, thereby converting the fuel into CO₂, H₂O and optionally N₂.

2. The method of claim 1, wherein the oxidizing agent is selected from the group consisting of an acid, a metal salt comprising an oxidizing anion, and an inorganic oxidizing reagent.

3. The method of claim 2, wherein the oxidizing anion is selected from the group consisting of a nitrate, a perchlorate, a chlorate, a hypochlorite, an azide, a peroxide, a superoxide, a high-valent oxide, an N-oxide, a persulfate, a dinitramide, a nitrocyanamide, a nitroarylcarboxylate, a tetrazolate, and hydrates thereof.

4. The method of claim 1, wherein the fuel is an organic compound selected from acetylacetone, CF₃COCH₂COCF₃, CH₃COCHFCOCH₃, CH₃COCH₂C(═NH)CF₃, CH₃C(═NH)CHFC(═NH)CH₃, CH₃COCH₂C(═NCH₃)CF₃, CH₃C(═NCH₃)CHFC(═NCH₃)CH₃, CH₃C(═NH)CHFC(═NCH₃)CH₃, Ph₂POCH₂COCH₃, urea, N-methylurea, citric acid, ascorbic acid, stearic acid, nitromethane, hydrazine, carbohydrazide, oxalyl dihydrazide, malonic acid dihydrazide, tetra formal tris azine, hexamethylenetetramine, and malonic anhydride.

5. The method of claim 1, wherein the fuel is a metal or ammonium salt comprising an organic anion selected from an acetylacetonate, a citrate, an oxalate, an ascorbate, and a tearate.

6. The method of claim 1, wherein the solvent or solvent mixture comprises an alkoxyalcohol.

7. The method of claim 1, wherein the metal oxide thin film comprises indium oxide (In₂O₃), indium zinc oxide (In—Zn—O), or indium gallium zinc oxide (In—Ga—Zn—O).

8. The method of claim 1, wherein the semiconductor precursor composition comprises two or more metal salts, wherein at least one of the metal salts comprises an oxidizing anion and at least one of the metal salts comprises a metal that is not indium and is selected from the group consisting of a Group 13 metal, a Group 14 metal, a Group 15 metal, a transition metal, and a lanthanide.

9. The method of claim 1, wherein the semiconductor precursor composition further comprises a second metal salt comprising gallium and either a fuel anion or an oxidizing anion, and a third metal salt comprising zinc and either a fuel anion or an oxidizing anion.

10. The method of claim 1, wherein the substrate comprises a flexible plastic substrate.

11. The method of claim 1, wherein a gate electrode component is present on the substrate, and a gate dielectric component is present on the gate electrode component, and the aerosol of the semiconductor precursor composition is contacted with the gate dielectric component so that the thin film semiconductor is formed adjacent to the gate dielectric component.

12. The method of claim 11, wherein the gate dielectric component comprises a metal oxide selected from the group consisting of SiO₂, Al₂O₃, ZrOₓ and HfO₂.

13. The method of claim 11, wherein the gate dielectric component comprises a polymer.

14. The method of claim 11, wherein the gate electrode component comprises a metal oxide.

15. The method of claim 14, comprising forming the metal oxide gate electrode component by contacting a substrate with an aerosol of a conductor precursor composition while maintaining the substrate at a temperature ranging between about 100° C. and about 350° C., wherein the conductor precursor composition comprises a fuel and one or more oxidizing agents in a solvent or solvent mixture, and wherein the fuel and/or at least one of the oxidizing agent(s) comprises a metal salt comprising indium and the fuel and the one or more oxidizing agents are present in amounts to allow metal oxide formation and complete combustion of the fuel, thereby converting the fuel into CO₂, H₂O and optionally N₂.

16. The method of claim 15, wherein the conductor precursor composition further comprises a second metal salt comprising tin and either a fuel anion or an oxidizing anion.

17. The method of claim 1, wherein the contacting step is performed using a spray-coating system, the spray-coating system comprising a reservoir for storing the semiconductor precursor composition, a compressed gas source attached to the reservoir for atomizing the semiconductor precursor composition into an aerosol, and a spray nozzle outlet for dispersing the aerosol.

18. The method of claim 17, wherein the spray nozzle outlet is kept at a vertical distance ranging between about 5 cm and about 100 cm from the substrate.

19. The method of claim 1, wherein the contacting step is performed until the metal oxide thin film has a thickness of at least about 20 nm.

20. The method of claim 1, wherein the contacting step is performed until the metal oxide thin film has a thickness of at least about 50 nm.
